(19) United States
(12) Patent Application Publication
(10) Pub. No.: US 2024/0074244 A1
(43) Pub. Date: Feb. 29, 2024

(54) DISPLAY PANEL AND DISPLAY DEVICE

(71) Applicant: Xiamen Tianma Display Technology Co., Ltd., Xiamen (CN)

(72) Inventors: Shui HE, Xiamen (CN); Liangqin XU, Xiamen (CN); Jiansheng Zhong, Xiamen (CN); Jinjin Yang, Xiamen (CN); Ying Liu, Xiamen (CN)

(73) Assignee: Xiamen Tianma Display Technology Co., Ltd., Xiamen (CN)

(21) Appl. No.: 18/387,240

(22) Filed: Nov. 6, 2023

(30) Foreign Application Priority Data
Jun. 30, 2023 (CN) 202310799411.0

(51) Int. Cl. H10K 59/122; H10K 59/126

(52) U.S. Cl. CPC H10K 59/122; H10K 59/126

(57) ABSTRACT

Provided are a display panel and a display device. The display panel includes a display region and a non-display region. The display region surrounds at least part of the non-display region. The non-display region includes an element disposition region and a bank disposition region surrounding at least part of the element disposition region. The bank disposition region is provided with a bank. The display panel includes a substrate, the bank is disposed on a side of the substrate; a light-emitting layer located on a side of the bank facing away from the substrate and including a first light-emitting portion located in the bank disposition region; and a first light-shielding structure located in the bank disposition region and on a side of the first light-emitting portion facing the substrate. The first light-emitting portion and the first light-shielding structure at least partially overlap along the thickness direction of the display panel.

This application claims priority to Chinese Patent Application No. 202310799411.0 filed Jun. 30, 2023, the disclosure of which is incorporated herein by reference in its entirety.

### TECHNICAL FIELD

The present invention relates to the field of display technology and, in particular, to a display panel and a display device.

### BACKGROUND

In an existing display panel, a bank disposition region is generally disposed between an active area hole (AA hole, AAH) and a display region. The bank disposition region is provided with a bank for preventing an organic encapsulation layer from entering the AAH.

However, in a laser lift-off (LLO) process, that is, in a process of lifting off a rigid substrate by the laser lift-off technology, laser easily vaporizes an organic light-emitting layer of the bank disposition region, lifting off the film and thereby affecting the structural stability of the display panel.

### SUMMARY

The present invention provides a display panel and a display device to solve the problem of lifting off a film caused by vaporization of an organic light-emitting layer in a laser lift-off process, improving the structural stability of the display panel.

In a first aspect, an embodiment of the present invention provides a display panel. The display panel includes a display region and a non-display region, and the display region surrounds at least part of the non-display region. The non-display region includes an element disposition region and a bank disposition region surrounding at least part of the element disposition region, and the bank disposition region is provided with a bank. The display panel further includes a substrate, where the bank is disposed on a side of the substrate; a light-emitting layer located on a side of the bank facing away from the substrate and including a first light-emitting portion located in the bank disposition region; and a first light-shielding structure located in the bank disposition region and on a side of the first light-emitting portion facing the substrate, where the first light-emitting portion and the first light-shielding structure at least partially overlap along a thickness direction of the display panel.

In a second aspect, an embodiment of the present invention provides a display panel. The display panel includes a display region and a non-display region, and the display region surrounds at least part of the non-display region. The non-display region includes an element disposition region and a barrier structure disposition region surrounding at least part of the element disposition region, and the barrier structure disposition region is provided with a barrier structure. The display panel further includes a substrate, where the barrier structure is disposed on a side of the substrate; a light-emitting layer located on a side of the barrier structure facing away from the substrate and including a second light-emitting portion located in the barrier structure disposition region, where at least part of the second light-emitting portion is disconnected at the barrier structure; and a second light-shielding structure located in the barrier structure disposition region and on a side of the second light-emitting portion facing the substrate, where the second light-emitting portion and the second light-shielding structure at least partially overlap along a thickness direction of the display panel.

In a third aspect, an embodiment of the present invention provides a display device including the display panel described in the first aspect or the second aspect.

### BRIEF DESCRIPTION OF DRAWINGS

To illustrate the technical solutions in the embodiments of the present invention or the technical solutions in the related art more clearly, drawings used in the description of the embodiments or the related art will be briefly described below. Apparently, though the drawings described below illustrate part of specific embodiments of the present invention, those skilled in the art may expand and extend to other structures and drawings according to the basic concepts of the device structure, driving method, and manufacturing method disclosed and indicated in the embodiments of the present invention. These are undoubtedly all within the scope of the claims of the present invention.

FIG. 1 is a diagram illustrating the sectional structure of a display panel in the related art.

FIG. 2 is a top diagram of a display panel according to an embodiment of the present invention.

FIG. 3 is a sectional diagram taken along the A-A′ line of FIG. 2.

FIG. 4 is another sectional diagram taken along the A-A′ line of FIG. 2.

FIG. 5 is another sectional diagram taken along the A-A′ line of FIG. 2.

FIG. 6 is another sectional diagram taken along the A-A′ line of FIG. 2.

FIG. 7 is another sectional diagram taken along the A-A′ line of FIG. 2.

FIG. 8 is a top diagram of another display panel according to an embodiment of the present invention.

FIG. 9 is a sectional diagram taken along the B-B′ line of FIG. 8.

FIG. 10 is another sectional diagram taken along the B-B′ line of FIG. 8.

FIG. 11 is a partial top diagram of a display panel according to an embodiment of the present invention.

FIG. 12 is a diagram illustrating the circuit structure of a sub-pixel according to an embodiment of the present invention.

FIG. 13 is a sectional diagram taken along the C-C′ line of FIG. 11.

FIG. 14 is a partial top diagram of another display panel according to an embodiment of the present invention.

FIG. 15 is a sectional diagram taken along the D-D′ line of FIG. 14.

FIG. 16 is another sectional diagram taken along the A-A′ line of FIG. 2.

FIG. 17 is another sectional diagram taken along the A-A′ line of FIG. 2.

FIG. 18 is another sectional diagram taken along the A-A′ line of FIG. 2.

FIG. 19 is another sectional diagram taken along the A-A′ line of FIG. 2.

FIG. 20 is another sectional diagram taken along the A-A′ line of FIG. 2.

FIG. 21 is another sectional diagram taken along the A-A′ line of FIG. 2.

FIG. 22 is another sectional diagram taken along the A-A′ line of FIG. 2.

FIG. 23 is another sectional diagram taken along the A-A′ line of FIG. 2.

FIG. 24 is another sectional diagram taken along the B-B′ line of FIG. 8.

FIG. 25 is another sectional diagram taken along the B-B′ line of FIG. 8.

FIG. 26 is another sectional diagram taken along the A-A′ line of FIG. 2.

FIG. 27 is a diagram illustrating the structure of a display device according to an embodiment of the present invention.

### DETAILED DESCRIPTION

In order that the objects, technical solutions and advantages of the present invention are clearer, the technical solutions of the present invention are described more clearly and completely hereinafter with reference to drawings of embodiments of the present invention and in conjunction with implementations. Apparently, the embodiments described herein are some embodiments, not all embodiments, of the present invention. All other embodiments obtained by those skilled in the art based on the basic concepts disclosed and indicated in embodiments of the present invention are within the scope of the present invention.

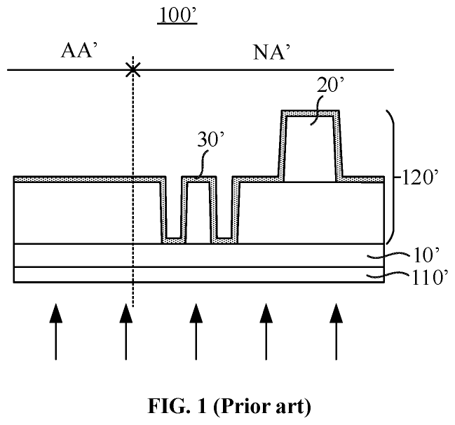

As described in the background, FIG. 1 is a diagram illustrating the sectional structure of a display panel in the related art. As shown in FIG. 1, the display panel 100′ includes a display region AA′ and a non-display region NA′. The non-display region NA′ includes a bank disposition region. It is to be understood that the bank disposition region is provided with a bank 20′ for blocking an organic encapsulation layer (not shown in FIG. 1), that is, preventing the organic encapsulation layer from entering other regions (for example, the AAH). When a substrate 10′ of the display panel 100′ is a flexible substrate, the substrate 10′ is generally formed on the flexible substrate 110′, and after other function layers 120′ are formed on the substrate 10′, the laser lift-off technology is generally used for lifting off and removing the flexible substrate 110′. However, since the transmittance of the non-display region NA′ is relatively high, that is, the transmittance of the bank disposition region is relatively high, laser can penetrate the substrate 10′ and vaporize a light-emitting layer 30′ of the bank disposition region, thereby lifting off a film and affecting the structural stability of the display panel.

Based on the preceding technical problems, embodiments of the present invention provide a display panel. The display panel includes a display region and a non-display region. The display region surrounds at least part of the non-display region. The non-display region includes an element disposition region and a bank disposition region surrounding at least part of the element disposition region. The bank disposition region is provided with a bank. The display panel further includes a substrate, where the bank is located on a side of the substrate; a light-emitting layer located on a side of the bank facing away from the substrate and including a first light-emitting portion located in the bank disposition region; and a first light-shielding structure located in the bank disposition region and on a side of the first light-emitting portion facing the substrate. The first light-emitting portion and the first light-shielding structure at least partially overlap along the thickness direction of the display panel.

In the technical solutions adopted, the bank disposition region is provided with the first light-shielding structure, and the first light-shielding structure is located on the side of the first light-emitting portion facing the substrate and at least partially overlaps the first light-emitting portion. In this way, the first light-shielding structure blocks the laser light so that some films of the display panel can be prevented from being lifted off due to vaporization of the first light-emitting portion caused by irradiating the first light-emitting portion of the light-emitting layer by the laser light in a process of lifting off the rigid substrate by laser, thereby improving the structural stability of the display panel.

The preceding is the core idea of the present application. The technical solutions in the embodiments of the present invention are described clearly and completely below in conjunction with the drawings in the embodiments of the present invention. Apparently, the embodiments described below are some embodiments, not all embodiments, of the present invention. Based on the embodiments of the present invention, all other embodiments obtained by those of ordinary skill in the art on the premise that no creative work is done are within the scope of the present invention.

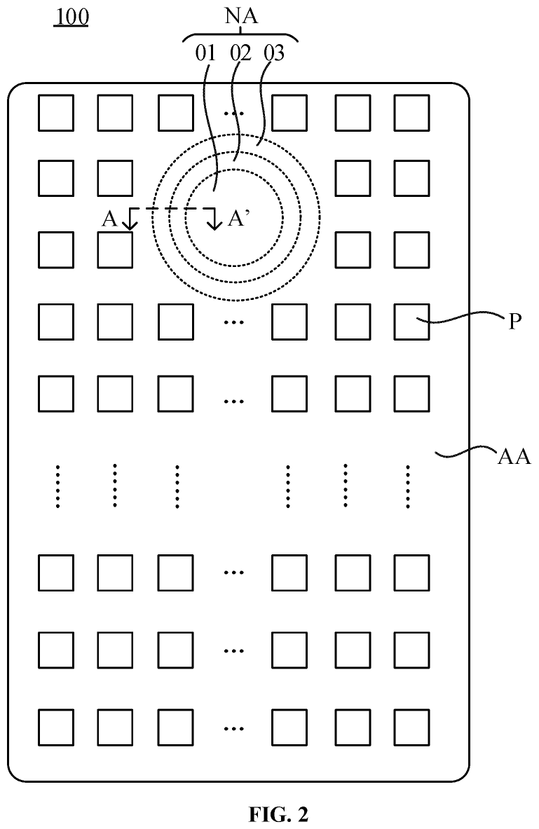

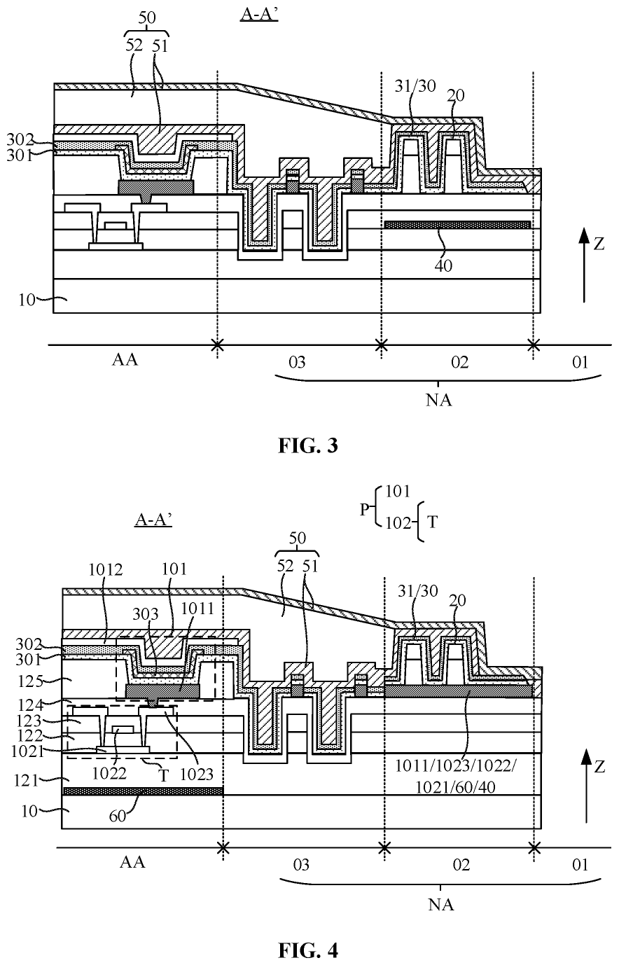

FIG. 2 is a top diagram of a display panel according to an embodiment of the present invention. FIG. 3 is a sectional diagram taken along the A-A′ line of FIG. 2. In conjunction with FIGS. 2 and 3, the display panel 100 includes a display region AA and a non-display region NA. The display region AA surrounds at least part of the non-display region NA. The non-display region NA includes an element disposition region 01 and a bank disposition region 02 surrounding at least part of the element disposition region 01. The bank disposition region 02 is provided with a bank 20. The display panel 100 further includes a substrate 10, where the bank 20 is located on a side of the substrate 10; a light-emitting layer 30 located on a side of the bank 20 facing away from the substrate 10 and including a first light-emitting portion 31 located in the bank disposition region 02; and a first light-shielding structure 40 located in the bank disposition region 02 and on a side of the first light-emitting portion 31 facing the substrate 10, where the first light-emitting portion 31 and the first light-shielding structure 40 at least partially overlap along the thickness direction Z of the display panel.

Referring to FIG. 2, FIG. 2 illustrates that the display region AA surrounds the non-display region NA, and that the bank disposition region 02 located in the non-display region NA is located between the element disposition region 01 and the display region AA and surrounds the element disposition region 01. It is to be noted that FIG. 2 is merely an exemplary illustration, but this is not limited thereto.

Referring to FIG. 3, the substrate 10 may be a multilayer structure. For example, the substrate 10 includes an organic layer and an inorganic buffer layer that are stacked. The material of the organic layer includes, but is not limited to, polyimide so that the organic layer can have high temperature resistance and good insulation. The material of the inorganic buffer layer includes, but is not limited to, silicon oxide or silicon nitride so that the inorganic buffer layer can block impurity ions escaping from the organic layer due to a high temperature process of other films formed on the substrate 10, so as to prevent the impurity ions escaping from the organic layer from affecting the performances of the other films formed on the substrate 10. Further, the substrate 10 may include two organic layers, and when the rigid substrate is lifted off and removed by laser, the integrity of an organic layer at least on a side away from the rigid substrate can be maintained without damage so that the structural integrity and the performance stability of the overall display panel can be ensured.

In conjunction with FIGS. 2 and 3, it is to be understood that the element disposition region 01 may be used for disposing elements, such as an optical sensor or a distance sensor for implementing other additional functions of a display module, such as an imaging function or a distance sensing function. Further, the element disposition region 01 may penetrate at least some films in the display panel 10 to form a via hole structure or a blind hole structure. In this embodiment of the present invention, the types of elements and open pores disposed in the element disposition region 01 are not specifically limited, and the open pores being via holes are only used as an example for illustration. Further, the bank disposition region 02 is further disposed between the element disposition region 01 and the display region AA, and the bank 20 is disposed in the bank disposition region 02, one or more banks may be provided, and the bank 20 is used for preventing an organic layer in an encapsulation layer from extending toward the element disposition region 01. Since the organic layer has a relatively good ability to absorb water and oxygen, at least one group of banks 20 in the bank disposition region 02 can prevent the organic layer from extending to the element disposition region 01 so that moisture or oxygen cannot extend to the display region AA along the organic layer, thereby ensuring the encapsulation effect of the display panel 100. FIG. 3 only exemplarily illustrates that two banks 20 are disposed in the bank disposition region 02 to avoid the epitaxy of the organic layer in the encapsulation layer more safely and stably, ensuring the encapsulation effect of the display panel 100.

The bank 20 may be formed by stacking multiple organic films. FIG. 3 is merely an exemplary illustration, but this is not limited herein.

With continued reference to FIG. 3, the light-emitting layer 30 includes a common light-emitting function layer that may include a hole injection layer, a hole transport layer, an electron blocking layer, a hole blocking layer, an electron transport layer, an electron injection layer and other films. For clarity, FIG. 3 only illustrates the hole transport layer 301 and the electron transport layer 302. It is to be understood that the common light-emitting function layer is formed by evaporation on the entire surface. In this way, the non-display region NA may also be vaporized to form a common light-emitting function layer including the first light-emitting portion 31 located in the bank disposition region 02.

Since the transmittance of at least a non-bank 20 structure in the bank disposition region 02 is relatively high, the laser penetrates the substrate 10 and easily vaporizes the first light-emitting portion 31, lifting off the film and thereby affecting the structural stability of the display panel. In this way, the first light-shielding structure 40 is disposed on a side of the first light-emitting portion 31 facing the substrate 10 in the bank disposition region 02, the size and shape of the first light-shielding structure 40 may be disposed according to actual needs, and along the thickness direction Z of the display panel, the first light-emitting portion 31 and the first light-shielding structure 40 can at least partially overlap to avoid vaporizing the first light-emitting portion 31 caused by irradiating the first light-emitting portion 31 by the laser, thereby improving the structural stability of the display panel.

It is to be noted that the first light-shielding structure 40 may be made of a metal material and may be a whole-layer structure or a patterned structure, as long as the first light-shielding structure 40 can be ensured to be able to perform light-shielding for the first light-emitting portion 31. Further, the first light-shielding structure 40 may be a one-layer or a multilayer structure and may use the existing metal films in the display panel for reuse or may be located in the same layer as the existing metal films to reduce the number of films disposed in the display panel, facilitating the lighter and thinner design. This may be disposed according to actual needs.

In addition, FIG. 3 only exemplarily illustrates some film structures of the display panel 100, and this is not limited herein. The specific film structures may be disposed according to actual needs.

In conclusion, in this embodiment, the bank disposition region is provided with the first light-shielding structure, and the first light-shielding structure is located on the side of the first light-emitting portion facing the substrate and at least partially overlaps the first light-emitting portion. In this way, the first light-shielding structure blocks the laser light so that some films of the display panel can be prevented from being lifted off due to vaporization of the first light-emitting portion caused by irradiating the first light-emitting portion of the light-emitting layer by the laser light in a process of lifting off the rigid substrate by laser, thereby improving the structural stability of the display panel.

In an embodiment, with continued reference to FIG. 3, the display panel further includes an encapsulation structure 50 located on a side of the light-emitting layer 30 facing away from the substrate 10. The encapsulation structure 50 includes an organic encapsulation layer 52 located between two inorganic encapsulation layers S1. The organic encapsulation layer 52 ends at the location of the bank 20.

The materials of the two inorganic encapsulation layers 51 may be the same or different. For example, the materials of the two inorganic encapsulation layers are silicon nitride.

Specifically, the two inorganic encapsulation layers 51 may be prepared by the chemical vapor deposition technology, and the organic encapsulation layer 52 may be prepared by the inkjet printing technology. To effectively limit the flow range of the organic encapsulation layer 52 of the encapsulation structure 50, the bank disposition region 02 is provided with the bank 20 to limit the boundaries of the organic encapsulation layer 52 so that the organic encapsulation layer 52 can be prevented from extending toward a side of the element disposition region 01, water and oxygen can be better prevented, and moisture or oxygen can be prevented from entering the display region AA along the organic encapsulation layer 52, thereby affecting the display effect of the display panel.

In an embodiment, FIG. 4 is another sectional diagram taken along the A-A′ line of FIG. 2. In conjunction with FIGS. 2 and 4, the display region AA includes multiple sub-pixels P. A sub-pixel P includes a light-emitting element 101 and a pixel circuit 102 that are interconnected. The light-emitting element 101 includes an anode 1011. The pixel circuit 102 includes a transistor T. The transistor T includes an active layer 1021, a gate 1022 and a source/drain electrode 1023. The display panel further includes a shield protection structure 60 located between a film in which the substrate 10 is located and a film in which the pixel circuit 1022 is located. The first light-shielding structure 40 is in the same layer as at least one of the anode 1011, the active layer 1021, the gate 1022, the source/drain electrode 1023, or the shield protection structure 60.

With continued reference to FIG. 4, the light-emitting element 101 includes the anode 1011, the light-emitting layer 30 and a cathode 1012 that are stacked. The light-emitting layer 30 includes multiple light-emitting composite layers 303 located in the display region AA. It is to be noted that the multiple light-emitting composite layers 303 are located in a pixel opening of a pixel defining layer. In this way, when an electric signal is applied to the anode 1011 and the cathode 1012, under the action of electric fields of the anode 1011 and the cathode 1012, a hole and an electron are transmitted to the multiple light-emitting composite layers 303 through the hole transport layer 301 and the electron transport layer 302 respectively and are composite in the multiple light-emitting composite layers 303 to emit light. It is to be understood that the specific film structure of the light-emitting layer 30 includes, but is not limited to, this shown in FIG. 3 and this may be disposed according to actual needs.

The light-emitting element 101 may emit red light, green light, blue light, or another color. According to different emitted colors of light-emitting elements 101, the materials of light-emitting composite layers 303 thereof are also different. This is not specifically limited in this embodiment of the present invention and may be disposed according to actual needs.

With continued reference to FIG. 4, FIG. 4 only exemplarily illustrates the structure of one transistor T in the pixel circuit 102. The transistor T includes the active layer 1021, the gate 1022 and the source/drain electrode 1023. The active layer 1021 may include an oxide semiconductor or silicon. The specific materials of the gate 1022 and the source/drain electrode 1023 may also be disposed by those skilled in the art according to actual cases. This is not limited herein. Exemplarily, the material of the active layer 1021 may select indium gallium zinc oxide or the like, the material of the gate 1022 may use molybdenum or the like, and the material of the source/drain electrode 1023 may use molybdenum/aluminum/molybdenum, titanium/aluminum/titanium, or the like. Since the active layer 1021 in the transistor T generates a photo-generated carrier after being irradiated by light, the leakage current of the transistor increases, thereby affecting the display picture quality of the display panel. Further, the shield protection structure 60 may be disposed between the film in which the substrate 10 is located and the film in which the pixel circuit 1022 is located to prevent the laser from penetrating the substrate to irradiate the active layer 1021, reduce the leakage current of the transistor T and improve the display effect of the display panel.

It is to be noted that the transistor T may be a top-gate structure or a bottom-gate structure. This is not specifically limited herein and may be disposed according to actual cases.

In addition, the display panel may further include a buffer layer 121, an interlayer insulating layer 122, a gate insulating layer 123, a planarization layer 124, the pixel defining layer 125 and others. However, this is not limited herein.

Further, the first light-shielding structure 40 may be in the same layer as at least one of the anode 1011, the active layer 1021, the gate 1022, the source/drain electrode 1023, or the shield protection structure 60. For one thing, the preparation process can be simplified, and for another thing, the number of films disposed in the display panel can be reduced, facilitating the lighter and thinner design of the display panel.

The material of the anode 101 may be a single-layer conductive film whose material may include one or a combination of an indium tin oxide (ITO) material, an indium zinc oxide (IZO) material, a carbon nanotube material, a graphene material, gold, or silver. Alternatively, the anode may also be a composite conductive film. The composite conductive film may be ITO, Ag and ITO that are stacked, ITO, Al and ITO that are stacked, Al and TiN that are stacked, or Al and MoOx that are stacked. This is not limited herein. Exemplarily, the anode 101 is ITO, Ag and ITO that are stacked, and the first light-shielding structure 40 may be in the same layer as a film in which Ag is located.

In an embodiment, with continued reference to FIG. 4, the first light-shielding structure 40 is at least in the same layer as a structure having the minimum film thickness among the anode 1011, the active layer 1021, the gate 1022, the source/drain electrode 1023 and the shield protection structure 60.

It is to be understood that FIG. 4 is only an exemplary structure of each film, that the thickness of the each film in the figure does not represent a band having an actual thickness, and that the actual thickness of the each film may be disposed according to actual needs. This is not specifically limited herein.

Specifically, the first light-shielding structure 40 may be in the same layer as the structure having the minimum film thickness among the anode 1011, the active layer 1021, the gate 1022, the source/drain electrode 1023 and the shield protection structure 60. In this way, the height of the bank disposition region 02 padded by the first light-shielding structure 40 is the minimum to ensure good structural stability of the bank disposition region 02, and the misalignment of different films in the bank disposition region 02 is not caused by disposing the first light-shielding structure 40 to ensure good structural stability in the bank disposition region 02 and the good overall stability of the display panel.

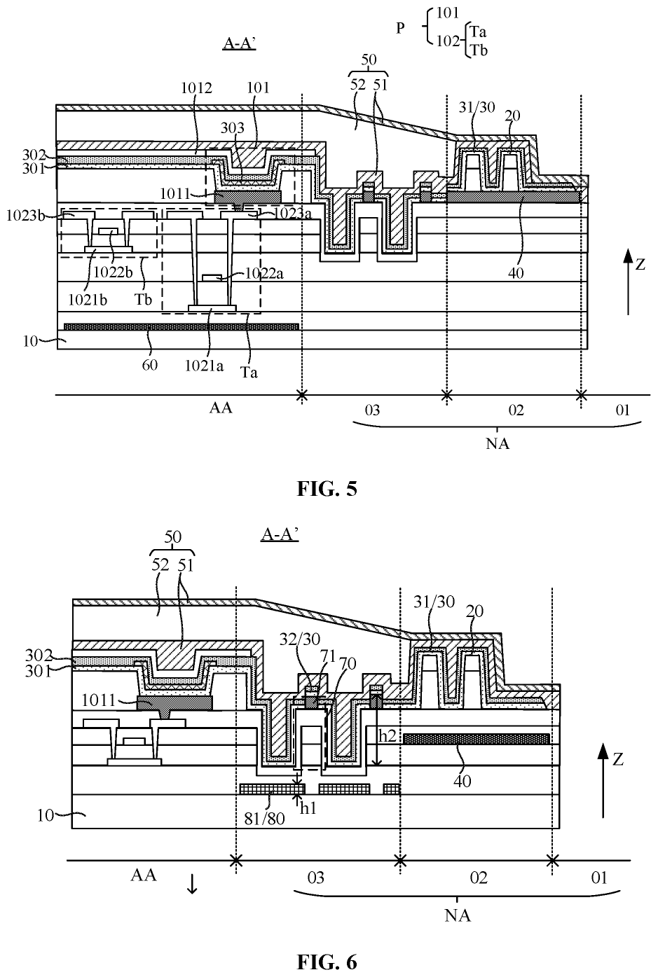

In an embodiment, FIG. 5 is another sectional diagram taken along the A-A′ line of FIG. 2. In conjunction with FIGS. 2 and 5, the display region AA includes the multiple sub-pixels P. The sub-pixel P includes the pixel circuit 102 and the light-emitting element 101 that are interconnected. The pixel circuit 102 includes a first transistor Ta and a second transistor Tb. The first transistor Ta includes a first active layer 1021a including silicon. The second transistor Tb includes a second active layer 1021b including an oxide.

Different from the sectional structure shown in FIG. 4, the pixel circuit 102 of the sub-pixel P includes the first transistor Ta and the second transistor Tb, the first transistor Ta includes the first active layer 1021a, a first gate 1022a and a first source/drain electrode 1023a, and the second transistor Tb includes the second active layer 1021b, a second gate 1022b and a second source/drain electrode 1023b, where the first active layer 1021a includes silicon, for example, may be a low-temperature polycrystalline silicon (LTPS) transistor. In this way, the first transistor Ta can form an LTPS-type transistor that has the advantages of a high switching speed, high carrier mobility and low power consumption. The second active layer 1021b includes an oxide that includes, but is not limited to, an indium gallium zinc oxide (IGZO). In this way, the second transistor Tb can form an IGZO-type transistor that has the advantages of a low production cost, low power consumption and small leakage current. In this way, the pixel circuit 102 according to this embodiment of the present invention may combine the preceding two types of transistors, that is, the LTPS-type transistor and the IGZO-type transistor, to form a low temperature polycrystalline oxide (LTPO)-type pixel circuit to ensure that the pixel circuit 102 can also have the performances of a high switching speed, high carrier mobility, low production cost, low power consumption and small leakage current and thereby ensuring the working performances of the pixel circuit 102 and the display panel.

With continued reference to FIG. 5, the first source/drain electrode 1023a and the second source/drain electrode 1023b may be located in the same layer. In this way, the two electrodes can be prepared and formed in the same process, simplifying the process and facilitating the implementation of a thinner display panel.

It is to be noted that to facilitate the understanding and description of the solution, unless otherwise specified, the structure of one transistor in the pixel circuit is exemplarily shown in the sectional diagrams of the display panel according to the embodiments below.

In an embodiment, FIG. 6 is another sectional diagram taken along the A-A′ line of FIG. 2. In conjunction with FIGS. 2 and 6, the non-display region NA further includes a barrier structure disposition region 03 provided with a barrier structure 70. The light-emitting layer 30 is located on a side of the barrier structure 70 facing away from the substrate 10 and includes a second light-emitting portion 32 located in the barrier structure disposition region 03. At least part of the second light-emitting portion 32 is disconnected at the barrier structure 70. The display panel 100 further includes a second light-shielding structure 80 located in the barrier structure disposition region 03 and on a side of the second light-emitting portion 32 facing the substrate 10. The second light-emitting portion 32 and the second light-shielding structure 80 at least partially overlap along the thickness direction Z of the display panel.

The barrier structure disposition region 03 may be located between the display region AA and the bank disposition region 02 or between the bank disposition region 02 and the element disposition region 01. FIG. 6 only exemplarily illustrates that the barrier structure disposition region 03 is located between the display region AA and the bank disposition region 02, but this is not limited herein.

One or more barrier structures 70 may be provided, which is not specifically limited in this embodiment of the present invention. FIG. 6 is merely an exemplary illustration, but this is not limited herein. It is to be understood that the barrier structure 70 may be formed by stacking multiple film structures, for example, including an insulating layer or a metal layer. This is not specifically limited herein and may be disposed according to actual needs.

With continued reference to FIG. 6, the light-emitting layer 30 further includes the second light-emitting portion 32 located in the barrier structure disposition region 03 and on the side of the barrier structure 70 facing away from the substrate 10. It is to be understood that the second light-emitting portion 32 includes a common light-emitting function layer, and that at least part of the second light-emitting portion 32 is disconnected at the barrier structure 70 to prevent moisture or oxygen from entering the display region AA along the second light-emitting portion 32 and avoid affecting the display effect of the display region AA.

Further, the display panel further includes the second light-shielding structure 80 located in the barrier structure disposition region 03 and on the side of the second light-emitting portion 32 facing the substrate 10. The size and shape of the second light-shielding structure 80 may be disposed according to actual needs. The second light-emitting portion 32 and the second light-shielding structure 80 at least partially overlap along the thickness direction Z of the display panel, which is used for performing light-shielding for the barrier structure disposition region 03 to prevent films of the display panel from being lifted off due to vaporization of the second light-emitting portion 32 caused by irradiating the second light-emitting portion 32 by the laser, improving the structural stability of the display panel.

It is to be noted that the second light-shielding structure 80 may be made of a metal material and may be a whole-layer structure or a patterned structure, as long as the second light-shielding structure 80 can be ensured to be able to perform laser-shielding for the second light-emitting portion 32. Further, the second light-shielding structure 80 may be a one-layer or a multilayer structure and may use the existing metal films in the display panel for reuse or may be located in the same layer as the existing metal films to reduce the number of films disposed in the display panel, facilitating the lighter and thinner design. This may be disposed according to actual needs.

In addition, the first light-shielding structure 40 and the second light-shielding structure 80 may be located in different films or in the same film, which may be disposed according to actual needs. FIG. 6 is merely an exemplary illustration, but this is not limited herein. Unless otherwise specified, this is also not specifically limited in the embodiments below.

In an embodiment, with continued reference to FIG. 6, the barrier structure 70 includes a metal barrier structure 71, the second light-shielding structure 80 includes multiple independent second light-shielding portions 81, and a second light-shielding portion 81 overlaps the gap between two adjacent metal barrier structures 71 along the thickness direction Z of the display panel.

The metal barrier structure 71 may include at least one metal film so that the barrier structure 70 itself can play a role of light-shielding. Exemplarily, FIG. 6 illustrates that the metal barrier structure 71 may be in the same layer as the anode 1011, but this is not limited herein.

Specifically, the second light-shielding structure 80 includes the multiple independent second light-shielding portions 81, according to different numbers of barrier structures 70, the specific number of metal barrier structures 71 is also different, and the gap between the two adjacent metal barrier structures 71 can still have a relatively high transmittance. In this way, along the thickness direction Z of the display panel, the multiple independent second light-shielding portions 81 can overlap gaps between two adjacent metal barrier structures 71 respectively so that the transmittance of the overall barrier structure disposition region 03 can be reduced, preventing the laser from irradiating the second light-emitting portion 32 of the barrier structure disposition region 03 and further preventing the second light-emitting portion 32 from being vaporized, thereby improving the structural stability of the display panel.

It is to be noted that the multiple independent second light-shielding portions 81 may be located in the same layer or may be different films, which may be disposed according to actual needs. FIG. 6 is merely an exemplary illustration.

In an embodiment, with continued reference to FIG. 6, the thickness h1 of the second light-shielding portion 81 is less than the thickness h2 of the barrier structure 70 along the thickness direction Z of the display panel.

Specifically, the second light-shielding portion 81 overlaps the gap between the two adjacent metal barrier structures 71. If the thickness h1 of the second light-shielding portion 81 is relatively large, the height difference between the surface of a side of the barrier structure 70 facing away from the substrate 10 and the surface of a side of the location of a non-barrier structure facing away from the substrate 10 can be reduced, and the light-emitting layer 30 cannot be ensured to be completely disconnected at the location of the barrier structure 70 and the location of the non-barrier structure, resulting in moisture and oxygen entering the display region AA along the light-emitting layer 30 and affecting the display effect of the display region AA. In this way, the thickness h1 of the second light-shielding portion 81 is less than the thickness h2 of the barrier structure 70 so that there can be a segment difference between a second light-emitting portion 32 at the location of the barrier structure 70 and a second light-emitting portion 32 at the location of the non-barrier structure to make the second light-emitting portion 32 disconnected at this location, ensuring that the light-emitting layer 30 of the display region AA cannot be eroded by water and oxygen and improving the display effect.

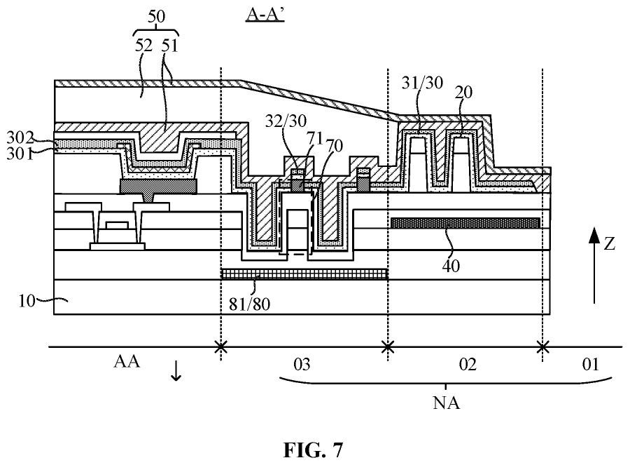

In an embodiment, FIG. 7 is another sectional diagram taken along the A-A′ line of FIG. 2. As shown in FIG. 7, along the thickness direction Z of the display panel, the second light-shielding structure 80 covers the barrier structure 70 and the gap between the barrier structure 70 and an adjacent barrier structure 70.

The second light-shielding structure 80 may be a whole-layer light-shielding structure or may also be formed by overlapping multiple light-shielding films. FIG. 7 is merely an exemplary illustration, but this is not limited herein.

Specifically, the second light-shielding structure 80 simultaneously covers the barrier structure 70 and the gap between the barrier structure 70 and the adjacent barrier structure 70 so that there can always be a certain segment difference between the second light-emitting portion 32 at the location of the barrier structure 70 and the second light-emitting portion 32 at the location of the non-barrier structure, and so that the second light-emitting portion 32 can be disconnected at this location, ensuring that the light-emitting layer 30 of the display region AA cannot be eroded by water and oxygen and improving the display effect.

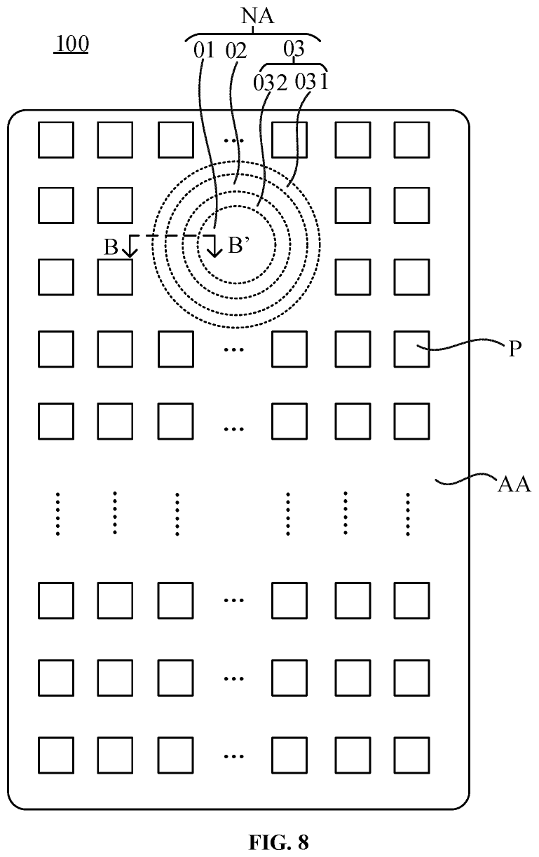

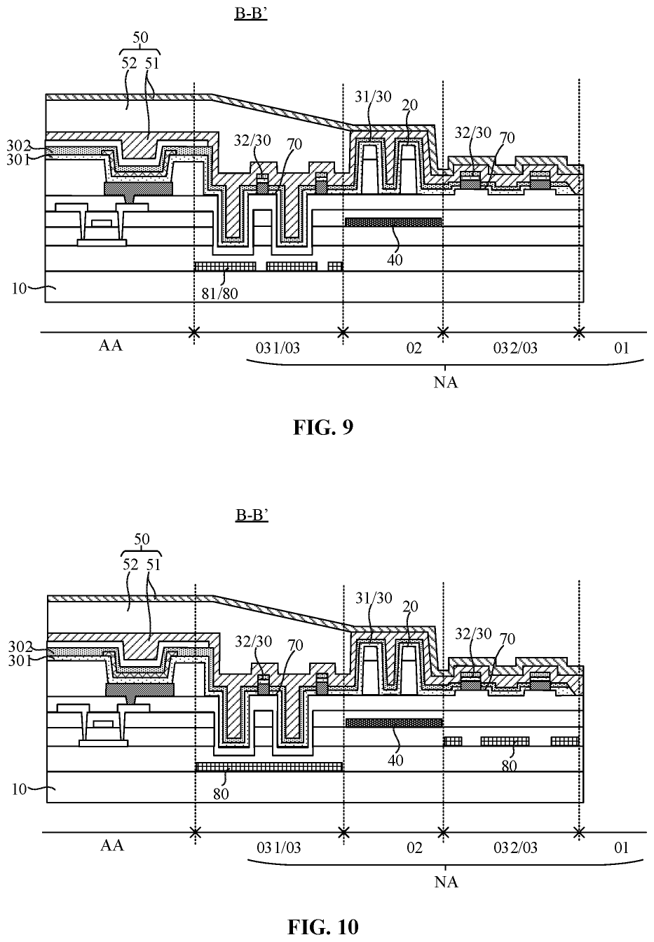

In an embodiment, FIG. 8 is a top diagram of another display panel according to an embodiment of the present invention, and FIG. 9 is a sectional diagram taken along the B-B′ line of FIG. 8. In conjunction with FIGS. 8 and 9, the barrier structure disposition region 03 includes a first barrier structure disposition region 031 and a second barrier structure disposition region 032. The first barrier structure disposition region 031 is located between the bank disposition region 02 and the display region AA, and the second barrier structure disposition region 032 is located between the bank disposition region 02 and the element disposition region 01. At least the first barrier structure disposition region 031 is provided with a second light-shielding structure 80.

Referring to FIG. 9, a barrier structure 70 is disposed in the first barrier structure disposition region 031 and the second barrier structure disposition region 032 so that the second light-emitting portion 32 located in the first barrier structure disposition region 031 and the second barrier structure disposition region 032 can be effectively disconnected from the light-emitting layer 30 in the display region AA, ensuring that the light-emitting layer 30 in the display region AA cannot be eroded by water and oxygen and thereby improving the display quality.

The number of barrier structures 70 in the first barrier structure disposition region 031 and the second barrier structure disposition region 032 may be disposed according to actual needs. This is not specifically limited herein. In addition, specific formation film structures of the barrier structures 70 in the first barrier structure disposition region 031 and the second barrier structure disposition region 032 may be the same or different. This is not specifically limited herein.

Further, since the first barrier structure disposition region 031 is much closer to the display region AA, at least the first barrier structure disposition region 031 is provided with the second light-shielding structure 80 so that the second light-shielding structure 80 can overlap the second light-emitting portion 32 located in the first barrier structure disposition region 031, and so that when the rigid substrate is lifted off by the laser, light-shielding can be at least performed on the second light-emitting portion 32 located in the first barrier structure disposition region 031, the films of the display panel can be prevented from being lifted off due to vaporization of the second light-emitting portion 32 caused by irradiating the second light-emitting portion 32 by the laser, vaporization of a common organic light-emitting layer can be prevented, the lift-off phenomenon can be prevented from extending to the display region AA, the normal performances of the common organic light-emitting layer located in the display region AA can be prevented from being affected, and the normal structure and function of the light-emitting layer 30 in the display region AA can be ensued on the premise that the structural stability of the display panel can be improved, thereby ensuring that the display region AA can normally display.

In an embodiment, FIG. 10 is another sectional diagram taken along the B-B′ line of FIG. 8. As shown in FIG. 10, the second barrier structure disposition region 032 is provided with a second light-shielding structure 80.

Specifically, the second light-shielding structure 80 disposed in the second barrier structure disposition region 032 may be a whole-layer structure or multiple independent structures. This may be disposed according to actual needs. Exemplarily, the barrier structure 70 located in the second barrier structure disposition region 032 includes the metal barrier structure, and along the thickness direction Z of the display panel, the second light-shielding structure 80 overlaps the region other than the non-metal barrier structure to perform light-shielding for the second light-emitting portion 32. In this way, the second light-shielding structure 80 is disposed in the first barrier structure disposition region 031 and the second barrier structure disposition region 032 so that the light-shielding effect of the second light-shielding structure 80 on the second light-emitting portion 32 can be increased, further preventing the second light-emitting portion 32 from being vaporized and improving the structural stability of the display panel.

It is to be noted that the second light-shielding structure 80 in the first barrier structure disposition region 031 and the second light-shielding structure 80 in the second barrier structure disposition region 032 may have the same shape or different shapes, which is not specifically limited herein. In addition, the second light-shielding structure 80 in the first barrier structure disposition region 031 and the second light-shielding structure 80 in the second barrier structure disposition region 032 may be located in the same layer or different layers, which is also not specifically limited herein. FIG. 10 is merely an exemplary illustration, and this is not limited herein and may be disposed according to actual needs.

In an embodiment, with continued reference to FIG. 10, the area of the first barrier structure disposition region 031 is S1, the coverage area of the second light-shielding structure 80 disposed in the first barrier structure disposition region 031 is S2, the area of the second barrier structure disposition region is S3, and the coverage area of the second light-shielding structure disposed in the second barrier structure disposition region 032 is S4, where (S2/S1)>(S4/S3).

Specifically, the area of the first barrier structure disposition region 031 is S1, and the coverage area of the second light-shielding structure 80 disposed in the first barrier structure disposition region 031 is S2, so the ratio of the coverage area of the second light-shielding structure 80 accounting for the area of the first barrier structure disposition region 031 is S2/S1. The larger the value of S2/S1, the better the light-shielding effect of the second light-shielding structure 80 on the first barrier structure disposition region 031. Similarly, the area of the second barrier structure disposition region is S3, and the coverage area of the second light-shielding structure 80 disposed in the second barrier structure disposition region 032 is S4, so the ratio of the coverage area of the second light-shielding structure 80 accounting for the area of the second barrier structure disposition region 032 is S4/S3. The larger the value of S4/S3, the better the light-shielding effect of the second light-shielding structure 80 on the second barrier structure disposition region 032. Further, since the first barrier structure disposition region 031 is much closer to the display region AA, and (S2/S1)>(S4/S3) is disposed, that is, the ratio S2/S1 of the coverage area of the second light-shielding structure 80 accounting for the area of the first barrier structure disposition region 031 is greater than the ratio S4/S3 of the coverage area of the second light-shielding structure 80 accounting for the area of the second barrier structure disposition region 032, the risk of the films being lifted off due to vaporization of the light-emitting layer 30 close to the display region AA can be reduced, improving the structural stability of the display panel, especially ensuring the structural stability of the display region AA.

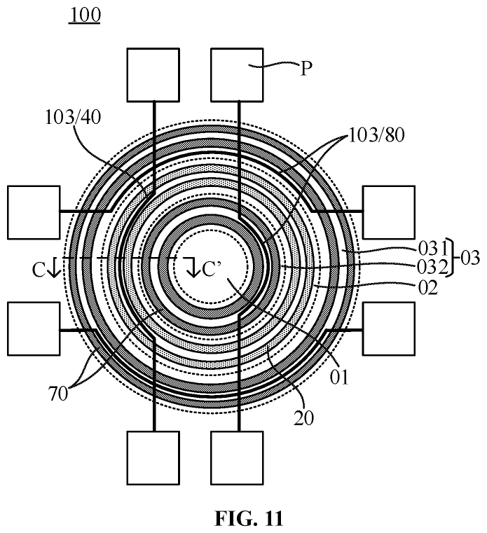

In an embodiment, FIG. 11 is a partial top diagram of a display panel according to an embodiment of the present invention. As shown in FIG. 11, the display region AA further includes the multiple sub-pixels P, and the display panel 100 further includes signal wires 103. The signal wires 103 are electrically connected to the multiple sub-pixels P and each include a wire portion surrounding part of the element disposition region 01. The wire portion also serves as a first light-shielding structure 40, and/or the wire portion also serves as a second light-shielding structure 80.

The arrangement mode of the multiple sub-pixels P in the display region AA may be disposed according to actual needs. For example, the arrangement mode of sub-pixels having different colors is a diamond pixel arrangement, or may be a standard RGB arrangement, a delta pixel arrangement, a pearl pixel arrangement, or a 2-in-1 pixel arrangement. This is not specifically limited herein. FIG. 11 exemplarily illustrates some sub-pixels P in the display region AA, but this is not limited herein. The bank disposition region 02 and the barrier structure disposition region 03 are further included between the element disposition region 01 and the display region AA. The barrier structure disposition region 03 may include the first barrier structure disposition region 031 and the second barrier structure disposition region 032. At least one bank 20 is disposed in the bank disposition region 02 and may surround the element disposition region 01. Meanwhile, at least one barrier structure 70 is disposed in the barrier structure disposition region 03 and may also surround the element disposition region 01.

With continued reference to FIG. 11, the signal wires 103 electrically connected to the multiple sub-pixels P may be used for transmitting gating signals that control transistors in the pixel circuit to be turned on or off or transmitting voltage signals (such as an initialization signal, a data voltage signal or a power signal). This is not specifically limited in this embodiment of the present invention and may be disposed according to actual needs.

Further, when sub-pixels P located on two sides of the element disposition region 01 are electrically connected to the same one signal wire 103, part of the signal wire 103 may surround part of the element disposition region 01 to avoid affecting the placement and operation of elements in the element disposition region 01. The wire portion surrounding part of the element disposition region 01 may also serve as the first light-shielding structure 40 and/or the second light-shielding structure 80 to simplify the line layout, reduce the layout space of the non-display region, improve the proportion of the display region of the display panel and improve the display effect of the display panel on the premise that the normal transmission of display signals can be ensured. Moreover, the film design and preparation process of the first light-shielding structure 40 and/or the second light-shielding structure 80 can be simplified, and the panel process can be simplified while the display panel can be thinner.

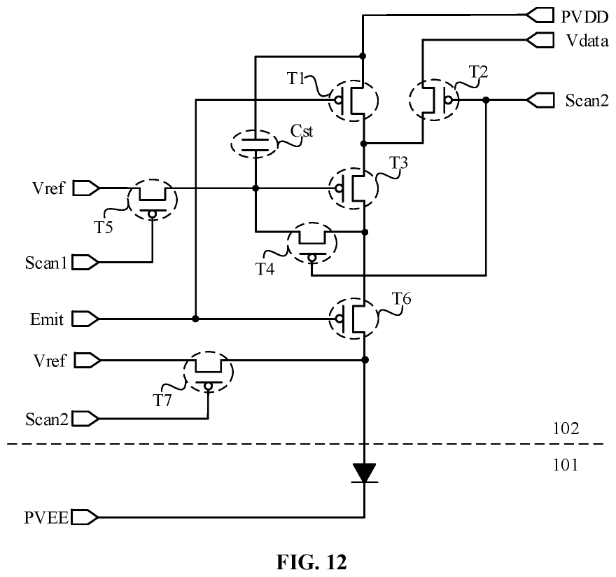

Exemplarily, that the pixel circuit structure of the sub-pixel P is a typical 7T1C (that is, 7 transistors and 1 storage capacitance) circuit is used as an example, and FIG. 12 is a diagram illustrating the circuit structure of a sub-pixel according to an embodiment of the present invention. As shown in FIG. 12, the sub-pixel P includes the pixel circuit 102 and the light-emitting element 101. The pixel circuit 102 includes a first light emission control transistor T1, a data write transistor T2, a drive transistor T3, a threshold compensation transistor T4, a first reset transistor T5, a second light emission control transistor T6, a second reset transistor T7 and a storage capacitance Cst. The first reset transistor T5 is used for supplying a reset voltage to the gate of the drive transistor T3 before a display stage. The second reset transistor T7 is used for supplying an initial reset voltage to the anode of the light-emitting element 101 before the display stage. A light emission control signal Emit controls the first light emission control transistor T1 and the second light emission control transistor T6 to be turned on or off. A first scan signal Scan1 controls the first reset transistor T5 to be turned on or off. A second scan signal Scan2 controls the second reset transistor T7, the data write transistor T2 and the threshold compensation transistor T4 to be turned on or off.

With continued reference to FIGS. 11 and 12, the signal wires 103 electrically connected to the multiple sub-pixels P may be gating signal lines that control the transistors in the pixel circuit 102 to be turned on or off, for example, first scan lines used for transmitting the first scan signal Scan1, second scan lines used for transmitting the second scan signal Scan2 and light emission control signal lines used for transmitting the light emission control signal Emit. The signal wires 103 may also be initialization signal lines used for transmitting a reset voltage signal Vref, data signal lines used for transmitting a data signal Vdata or power signal lines used for transmitting a power signal (PVDD or PVEE). This is not specifically limited in this embodiment of the present invention and may be disposed according to actual cases.

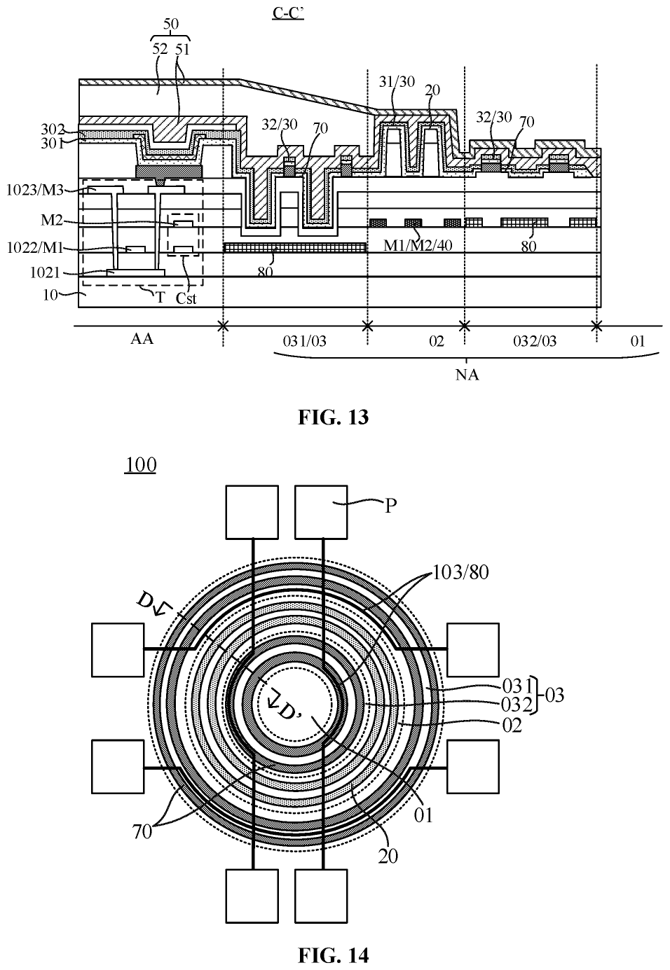

In an embodiment, FIG. 13 is a sectional diagram taken along the C-C′ line of FIG. 11. In conjunction with FIGS. 11, 12 and 13, the signal wires 103 includes a gating signal line and an initialization signal line. The gating signal line or the initialization signal line also serves as a first light-shielding structure 40.

Exemplarily, referring to FIG. 12, the gating signal line may refer to a first scan line used for transmitting the first scan signal Scant, a second scan line used for transmitting the second scan signal Scan2 or a light emission control signal line used for transmitting the light emission control signal Emit. The initialization signal line may refer to an initialization signal line used for transmitting the reset voltage signal Vref.

With continued reference to FIG. 13, a transistor T of a second pixel circuit 102 includes an active layer 1021, a gate 1022 and a source/drain electrode 1023. The transistor T may be any transistor in the pixel circuit 102, and this is not specifically limited herein. The display panel at least includes a first metal layer M1, a second metal layer M2 and a third metal layer M3. The first metal layer M1 may include the gate 1022 of the transistor T and a lower plate of the storage capacitance Cst. The second metal layer M2 includes an upper plate of the storage capacitance Cst of the pixel circuit 102. The third metal layer M3 may include the source/drain electrode 1023 of the transistor T.

Specifically, the first metal layer M1 and the second metal layer M2 may be made of molybdenum and may also include the gating signal line and/or the initialization signal line. Since the gating signal line and the initialization signal line each have a smaller thickness than the data signal line and the power signal line, a wire portion of the gating signal line or the initialization signal line which surrounds part of the element disposition region 01 is disposed in the bank disposition region 02 to be also served as a first light-shielding structure 40. In this way, the line layout can be simplified, the layout space of the non-display region can be reduced, and the film design and preparation process of the first light-shielding structure 40 and/or the second light-shielding structure 80 can be simplified. Moreover, the overall flatness of the bank disposition region 02 can be further ensured, the misalignment of different films in the bank disposition region 02 caused by adding the first light-shielding structure 40 can be prevented, and the good structural stability in the bank disposition region 02 can be ensured.

It is to be noted that the second light-shielding structure 80 in this embodiment may be disposed without limits according to actual needs. FIG. 13 is merely an exemplary illustration, but this is not limited.

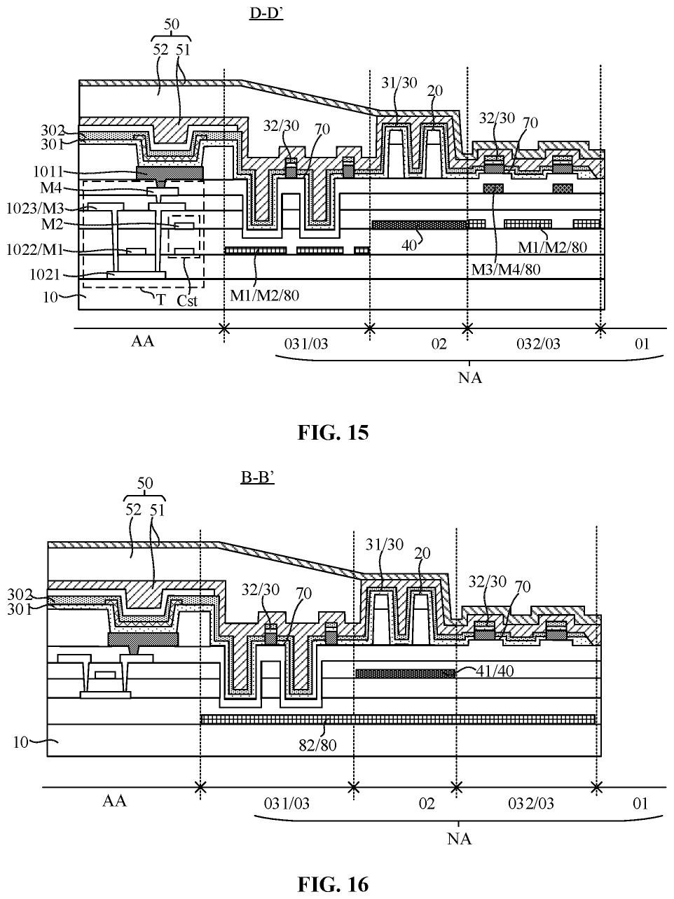

In an embodiment, FIG. 14 is a partial top diagram of another display panel according to an embodiment of the present invention, and FIG. 15 is a sectional diagram taken along the D-D′ line of FIG. 14. In conjunction with FIGS. 12, 14 and 15, the signal wires 103 include the gating signal line, a data signal line, the initialization signal line and a power signal line. The gating signal line, the data signal line, the initialization signal line and the power signal line also serve as second light-shielding structures 80. Along the thickness direction Z of the display panel, the gating signal line or the initialization signal line overlaps the gap between two adjacent barrier structures 70, and the data signal line or the power signal line overlaps the barrier structure 70.

Exemplarily, referring to FIG. 12, the gating signal line may refer to the first scan line used for transmitting the first scan signal Scan1, the second scan line used for transmitting the second scan signal Scan2 or the light emission control signal line used for transmitting the light emission control signal Emit. The initialization signal line may refer to the initialization signal line used for transmitting the reset voltage signal Vref. The data signal line may refer to a data signal line used for transmitting the data signal Vdata. The power signal line may refer to a power signal line used for transmitting the power signal (PVDD or PVEE). The gating signal line, the data signal line, the initialization signal line and the power signal line also serve as second light-shielding structures 80 to simplify the line layout, reduce the layout space of the non-display region and simplify the film designs and preparation processes of the second light-shielding structures 80 at the same time.

With continued reference to FIG. 15, the display panel further includes other metal layers such as a fourth metal layer M4. The fourth metal layer M4 may be an intermediate connection layer between the anode of the light-emitting element 101 and the source/drain electrode of the transistor, avoiding deep punching between the anode and the source/drain electrode and ensuring connection stability of the anode and the source/drain electrode. The first metal layer M1 and the second metal layer M2 may further each include a gating signal line and/or an initialization signal line, and the third metal layer M3 and the fourth metal layer M4 may further each include a data signal line and/or a power signal line. Since the gating signal line and the initialization signal line each have a smaller thickness than the data signal line and the power signal line, a wire portion of the gating signal line or the initialization signal line which surrounds part of the element disposition region 01 overlaps the gap between the two adjacent barrier structures 70, and a wire portion of the data signal line or the power signal line which surrounds part of the element disposition region 01 overlaps the barrier structure 70, where the barrier structure 70 may be located in the first barrier structure disposition region 031 or the second barrier structure disposition region 032, which is not specifically limited herein. In this way, when the signal wires 103 can be ensured to perform light-shielding for the second light-emitting portion 32 located in the barrier structure disposition region 03, there can be a certain height segment difference between the location of the barrier structure and the location of the non-barrier structure at the same time so that the second light-emitting portion 32 can be disconnected at this location, water and oxygen can be prevented from entering the display region AA along the light-emitting layer 30, and the display effect of the display region AA can be ensured.

In an embodiment, with continued reference to FIG. 6, 7 9 or 10, the area of the bank disposition region 02 is S5, the coverage area of the first light-shielding structure 40 is S6, the area of the barrier structure disposition region 03 is S7, and the sum of the coverage area of the barrier structure 70 and the coverage area of the second light-shielding structure 80 is S8, where |(S6/S5)−(S8/S7)|/{[(S6/S5)+(S8/S7)]/2}20%.

Specifically, the area of the bank disposition region 02 is S5, and the coverage area of the first light-shielding structure 40 disposed in the bank disposition region 02 is S6, so the ratio of the coverage area of the first light-shielding structure 40 accounting for the area of the bank disposition region 02 is S6/S5. The larger the value of S6/S5, the better the light-shielding effect of the first light-shielding structure 40 on the bank disposition region 02. Since the barrier structure 70 may include a metal barrier structure, the barrier structure 70 itself can play a role of light-shielding. In this case, the area of the barrier structure disposition region 03 is S7, and the sum of the coverage area of the barrier structure 70 and the coverage area of the second light-shielding structure 80 is S8, so the larger the value of S8/S7, the better the light-shielding effect of the barrier structure 70 and the second light-shielding structure 80 on the barrier structure disposition region 03.

Further, when |(S6/S5)−(S8/S7)|/{[(S6/S5)+(S8/S7)]/2}≤20%, that is, the difference between the ratio of the coverage area of the first light-shielding structure 40 on the bank disposition region 02 and the ratio of the coverage area of the barrier structure 70 and the second light-shielding structure 80 on the barrier structure disposition region 03, and a ratio accounting for the average value of the two is less than 20%, the overall flatness of the bank disposition region 02 and the barrier structure disposition region 03 of the display panel can be ensured, and the light-shielding effect can be relatively consistent. In this case, the light-shielding structures of the bank disposition region 02 and the barrier structure disposition region 03 have a relatively uniform reflection effect on light, helping improve the display effect of the display panel. FIG. 16 is another sectional diagram taken along the A-A′ line of FIG. 2. As shown in FIG. 16, the first light-shielding structure 40 includes a first overall light-shielding structure 41, and the second light-shielding structure 80 includes a second overall light-shielding structure 82.

Specifically, the first overall light-shielding structure 41 and the second overall light-shielding structure 82 may be each a whole-film structure. In this way, the disposition mode of the first light-shielding structure 40 and the second light-shielding structure 80 can be simpler, helping simplify the preparation process. Meanwhile, the light interference or diffraction caused by forming a structure similar to a grating by the multiple independent light-shielding structures can be prevented from being caused, improving the display quality of the display panel.

It is to be noted that the first overall light-shielding structure 41 and the second overall light-shielding structure 82 may be located in different films or in the same film. FIG. 16 is merely an exemplary illustration, but this is not limited herein.

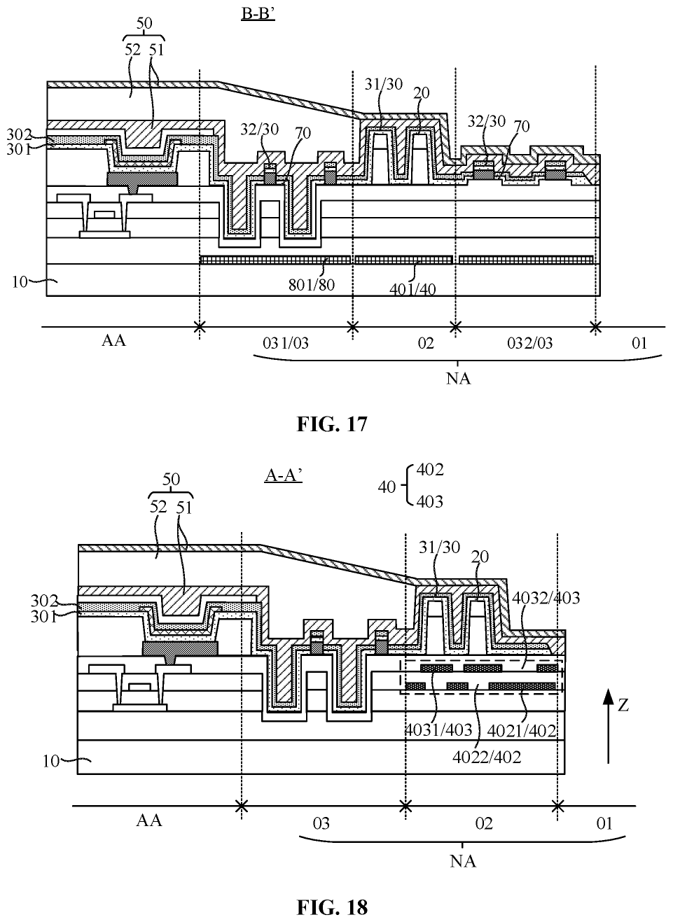

In an embodiment, FIG. 17 is another sectional diagram taken along the A-A′ line of FIG. 2. As shown in FIG. 17, the first light-shielding structure 40 includes at least one first light-shielding layer 401, the second light-shielding structure 80 includes at least one second light-shielding layer 801, and the at least one first light-shielding layer 401 and the at least one second light-shielding layer 801 are in the same layer.

Specifically, the at least one first light-shielding layer 401 and the at least one second light-shielding layer 801 are located in the same layer, may be simultaneously prepared and formed in the same process and are made of the same material. In this way, the number of films disposed in the display panel can be reduced, facilitating the lighter and thinner design of the display panel.

It is to be noted that the first light-shielding structure 40 and the second light-shielding structure 80 may each include multiple independent structures or may be each an overall structure. FIG. 17 is merely an exemplary illustration. Moreover, when the first light-shielding structure 40 and the second light-shielding structure 80 each include multiple layers of light-shielding structures, one of the multiple layers of light-shielding structures in the first light-shielding structure 40 is in the same layer as one of the multiple layers of light-shielding structures in the second light-shielding structure 80, or the first light-shielding structure 40 and the second light-shielding structure 80 have the same film disposition mode, that is, any layer of light-shielding structures in the first light-shielding structure 40 is in the same layer as one layer of light-shielding structures in the second light-shielding structure 80, and any layer of light-shielding structures in the second light-shielding structure 80 is in the same layer as one layer of light-shielding structure in the first light-shielding structure 40.

Based on any one of the preceding embodiments, FIG. 18 is another sectional diagram taken along the A-A′ line of FIG. 2. As shown in FIG. 18, the first light-shielding structure 40 includes a third light-shielding layer 402 and a fourth light-shielding layer 403 that are stacked, the third light-shielding layer 402 includes multiple first light-shielding patterns 4021, and the fourth light-shielding layer 403 includes multiple second light-shielding patterns 4031. Orthographic projections of the multiple first light-shielding patterns 4021 on the plane on which the substrate 10 is located and orthographic projections of the multiple second light-shielding patterns 4031 on the plane on which the substrate 10 is located are staggered, and the orthographic projection of the third light-shielding layer 402 on the plane on which the substrate 10 is located and the orthographic projection of the fourth light-shielding layer 403 on the plane on which the substrate 10 is located cover the orthographic projection of the first light-emitting portion 31 on the plane on which the substrate 10 is located.

The third light-shielding layer 402 and the fourth light-shielding layer 403 may be stacked structures adjacent to each other or stacked structures not adjacent to each other, that is, metal layers and/or insulating layers are spaced apart and disposed between the third light-shielding layer 402 and the fourth light-shielding layer 403. This is not specifically limited in this embodiment of the present invention and may be disposed according to actual needs. FIG. 18 is merely an exemplary illustration, but this is not limited herein.

Specifically, the third light-shielding layer 402 includes the multiple first light-shielding patterns 4021 and first gaps 4022 located between adjacent first light-shielding patterns 4021, and the fourth light-shielding layer 403 includes the multiple second light-shielding patterns 4031 and second gaps 4032 located between adjacent second light-shielding patterns 4031. The orthographic projections of the multiple first light-shielding patterns 4021 on the plane on which the substrate 10 is located overlap orthographic projections of the second gaps 4032 on the plane on which the substrate 10 is located, and the area of the orthographic projection of a first light-shielding pattern 4021 on the plane on which the substrate 10 is located is greater than the area of the orthographic projection of a second gap 4032 on the plane on which the substrate 10 is located; and the orthographic projections of the multiple second light-shielding patterns 4031 on the plane on which the substrate 10 is located overlap orthographic projections of the first gaps 4022 on the plane on which the substrate 10 is located, and the area of the orthographic projection of a second light-shielding pattern 4031 on the plane on which the substrate 10 is located is greater than the area of the orthographic projection of a first gap 4022 on the plane on which the substrate 10 is located. In this way, the orthographic projection of the third light-shielding layer 402 on the plane on which the substrate 10 is located and the orthographic projection of the fourth light-shielding layer 403 on the plane on which the substrate 10 is located can completely cover the orthographic projection of the first light-emitting portion 31 on the plane on which the substrate 10 is located to ensure that the first light-shielding structure 40 can completely perform light-shielding for the first light-emitting portion 31 and prevent the films of the display panel from being lifted off due to vaporization of the first light-emitting portion caused by irradiating the first light-emitting portion 31 by the laser so that the structural stability of the display panel can be improved.

Further, a second light-shielding structure may be disposed in the barrier structure disposition region 03 and may be provided with a fifth light-shielding layer and a sixth light-shielding layer (not shown in FIG. 18) that are stacked. The fifth light-shielding layer includes multiple third light-shielding patterns, and the sixth light-shielding layer includes multiple fourth light-shielding patterns. Orthographic projections of the multiple third light-shielding patterns on the plane on which the substrate is located and orthographic projections of the multiple fourth light-shielding patterns on the plane on which the substrate is located are staggered, and the orthographic projection of the fifth light-shielding layer on the plane on which the substrate is located and the orthographic projection of the sixth light-shielding layer on the plane on which the substrate is located cover the orthographic projection of the second light-emitting portion on the plane on which the substrate is located. It is to be understood that the fifth light-shielding layer and the sixth light-shielding layer of the second light-shielding structure may also be films adjacent to each other or films spaced apart, and the second light-shielding structure has a disposition mode similar to the first light-shielding structure. Details are not repeated herein.

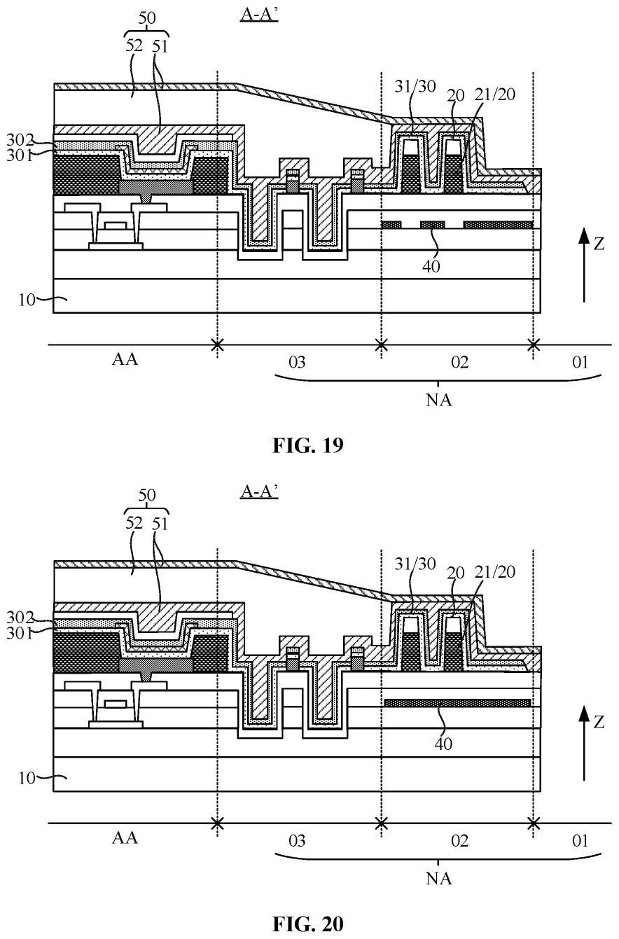

In an embodiment, FIG. 19 is another sectional diagram taken along the A-A′ line of FIG. 2. As shown in FIG. 19, the bank 20 includes a light-nontransmissive bank 21, and along the thickness direction Z of the display panel, the first light-shielding structure 40 overlaps the gap between two adjacent light-nontransmissive banks 21.

Specifically, the bank 20 may be formed by stacking multiple organic films. Some insulating layers in the display panel may be made of a black material or another light-shielding material. For example, the pixel defining layer, the planarization layer or a passivation layer may be made of a black material or another light-shielding material. FIG. 19 only exemplarily illustrates that some films are made of a light-shielding material. For example, the pixel defining layer is a black pixel defining layer (BPDL) so that part of the light-nontransmissive bank 21 can be black while the other part of the light-nontransmissive bank 21 can be light-transmissive. However, this is not limited herein and may be adaptively disposed according to actual cases. In this way, the light-nontransmissive bank 21 itself can block the laser, and the film design and preparation process of the first light-shielding structure 40 and/or the second light-shielding structure 80 can be simplified.

It is to be noted that, to ensure the normal operation of the overall display panel, films formed by the black material or another light-shielding material in other regions that need light transmission need to be removed, for example, the black pixel defining layer needs to perform a hollow-out removal processing on a light-transmissive region. Details are not described herein, and this may be disposed according to actual cases.

Further, FIG. 20 is another sectional diagram taken along the A-A′ line of FIG. 2. As shown in FIG. 20, along the thickness direction Z of the display panel, the first light-shielding structure 40 overlaps the light-nontransmissive bank 21 and the gap between the light-nontransmissive bank 21 and an adjacent light-nontransmissive bank 21 to further reduce the transmittance of the overall bank disposition region 02, improve the light-shielding effect and prevent the films of the display panel from being lifted off due to vaporization of the first light-emitting portion 31 caused by irradiating the first light-emitting portion 31 by the laser light so that the structural stability of the display panel can be improved. Meanwhile, the overall flatness of the bank disposition region 02 can be ensured, the misalignment of different films in the bank disposition region 02 caused by adding the first light-shielding structure 40 can be prevented, and the good structural stability in the bank disposition region 02 can be ensured. Optionally, based on any one of the preceding embodiments, the first light-shielding structure 40 is electrically connected to a fixed potential terminal.

Specifically, the first light-shielding structure 40 may be made of metal that is easy to form a coupling capacitance with other metal films. In this way, the first light-shielding structure 40 can be electrically connected to the fixed potential terminal to avoid interference to display due to other coupled electric signals caused by potential suspension and improve the display effect of the panel.

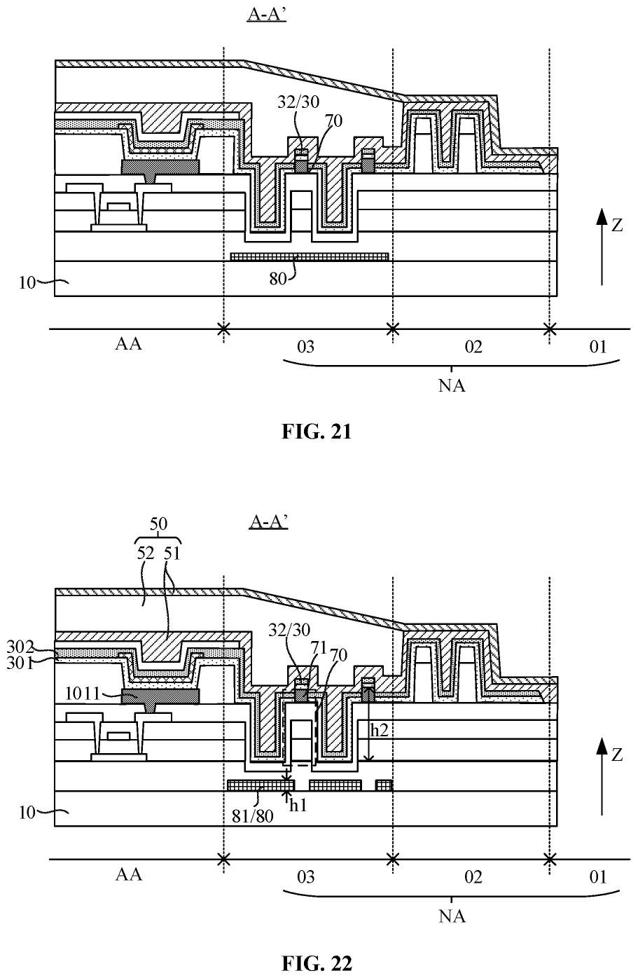

Based on the same inventive concept, an embodiment of the present invention further provides a display panel, and with continued reference to FIG. 2, FIG. 21 is another sectional diagram taken along the A-A′ line of FIG. 2. In conjunction with FIGS. 2 and 21, the display region 100 includes the display region AA and the non-display region NA. The display region AA surrounds at least part of the non-display region NA. The non-display region NA includes the element disposition region 01 and the barrier structure disposition region 03 surrounding at least part of the element disposition region 01 and provided with the barrier structure 70. The display panel 100 further includes the substrate 10, where the barrier structure 70 is disposed on the side of the substrate 10; the light-emitting layer 30 located on the side of the barrier structure 70 facing away from the substrate 10 and including the second light-emitting portion 32 located in the barrier structure disposition region 03, where the second light-emitting portion 32 is at least partially disconnected at the barrier structure 70; and the second light-shielding structure 80 located in the barrier structure disposition region 03 and on the side of the second light-emitting portion 32 facing the substrate 10. The second light-emitting portion 32 and the second light-shielding structure 80 at least partially overlap along the thickness direction Z of the display panel.

The barrier structure disposition region 03 is located in the display region AA and the element disposition region 01. In addition, the bank disposition region 02 may be further included between the display region AA and the element disposition region 01. The specific positional relation between the barrier structure disposition region 03 and the bank disposition region 02 may be disposed according to actual cases. FIGS. 2 and 21 are merely exemplary illustrations, but this is not limited herein.

One or more barrier structures 70 may be disposed in the barrier structure disposition region 03 so that the second light-emitting portion 32 can be disconnected at the barrier structure 70 to prevent the display effect of the display region AA from being affected by moisture or oxygen entering the display region AA along the second light-emitting portion 32. It is to be understood that the barrier structure 70 may be formed by stacking multiple film structures, for example, including an insulating layer or a metal layer. This is not specifically limited herein and may be disposed according to actual needs.

With continued reference to FIG. 21, the light-emitting layer 30 further includes the second light-emitting portion 32 located in the barrier structure disposition region 03 and on the side of the barrier structure 70 facing away from the substrate 10. It is to be understood that the second light-emitting portion 32 includes the common light-emitting function layer, and that the second light-emitting portion 32 is at least partially disconnected at the barrier structure 70 to prevent moisture or oxygen from entering the display region AA along the second light-emitting portion 32 and avoid affecting the display effect of the display region AA.

Further, the display panel further includes the second light-shielding structure 80 located in the barrier structure disposition region 03 and on the side of the second light-emitting portion 32 facing the substrate 10. The size and shape of the second light-shielding structure 80 may be disposed according to actual needs. The second light-emitting portion 32 and the second light-shielding structure 80 at least partially overlap along the thickness direction Z of the display panel, which is used for performing light-shielding for the barrier structure disposition region 03 to prevent the films of the display panel from being lifted off due to vaporization of the second light-emitting portion 32 caused by irradiating the second light-emitting portion 32 by the laser, improving the structural stability of the display panel.

It is to be noted that the second light-shielding structure 80 may be made of a metal material and may be a whole-layer structure or a patterned structure, as long as the second light-shielding structure 80 can be ensured to be able to perform laser-shielding for the second light-emitting portion 32. Further, the second light-shielding structure 80 may be a one-layer or a multilayer structure and may use the existing metal films in the display panel for reuse or may be located in the same layer as the existing metal films to reduce the number of films disposed in the display panel, facilitating the lighter and thinner design. This may be disposed according to actual needs. In this embodiment, the barrier structure disposition region is provided with the second light-shielding structure, and the second light-shielding structure is located on the side of the second light-emitting portion facing the substrate and at least partially overlaps the second light-emitting portion. In this way, the second light-shielding structure blocks the laser light so that some films of the display panel can be prevented from being lifted off due to vaporization of the second light-emitting portion caused by irradiating the second light-emitting portion of the light-emitting layer by the laser light in a process of lifting off the rigid substrate by laser, thereby improving the structural stability of the display panel.

In an embodiment, FIG. 22 is another sectional diagram taken along the A-A′ line of FIG. 2. As shown in FIG. 22, the barrier structure 70 includes the metal barrier structure 71, the second light-shielding structure 80 includes the multiple independent second light-shielding portions 81, and the second light-shielding portion 81 overlaps the gap between the two adjacent metal barrier structures 71 along the thickness direction Z of the display panel.

The metal barrier structure 71 may include at least one metal film so that the barrier structure 70 itself can play a role of light-shielding. Exemplarily, FIG. 22 illustrates that the metal barrier structure 71 may be in the same layer as the anode 1011, but this is not limited herein.

Specifically, the second light-shielding structure 80 includes the multiple independent second light-shielding portions 81, according to different numbers of barrier structures 70, the specific number of metal barrier structures 71 is also different, and the gap between the two adjacent metal barrier structures 71 can still have a relatively high transmittance. In this way, along the thickness direction Z of the display panel, the multiple independent second light-shielding portions 81 can overlap gaps between two adjacent metal barrier structures 71 respectively so that the transmittance of the overall barrier structure disposition region 03 can be reduced, preventing the laser from irradiating the second light-emitting portion 32 of the barrier structure disposition region 03 and further preventing the second light-emitting portion 32 from being vaporized, thereby improving the structural stability of the display panel.

It is to be noted that the multiple independent second light-shielding portions 81 may be located in the same layer or may be different films, which may be disposed according to actual needs. FIG. 22 is merely an exemplary illustration.

In an embodiment, with continued reference to FIG. 22, the thickness h1 of the second light-shielding portion 81 is less than the thickness h2 of the barrier structure 70 along the thickness direction Z of the display panel.

Specifically, the second light-shielding portion 81 overlaps the gap between two adjacent metal barrier structures 71. If the thickness h1 of the second light-shielding portion 81 is relatively large, the height difference between the surface of a side of the barrier structure 70 facing away from the substrate 10 and the surface of a side of the location of a non-barrier structure facing away from the substrate 10 can be reduced, and the light-emitting layer 30 cannot be ensured to be completely disconnected at the location of the barrier structure 70 and the location of the non-barrier structure, resulting in moisture and oxygen entering the display region AA along the light-emitting layer 30 and affecting the display effect of the display region AA. In this way, the thickness h1 of the second light-shielding portion 81 is less than the thickness h2 of the barrier structure 70 so that there can be a segment difference between the second light-emitting portion 32 at the location of the barrier structure 70 and the second light-emitting portion 32 at the location of the non-barrier structure to make the second light-emitting portion 32 disconnected at this location, ensuring that the light-emitting layer 30 of the display region AA cannot be eroded by water and oxygen and improving the display effect.

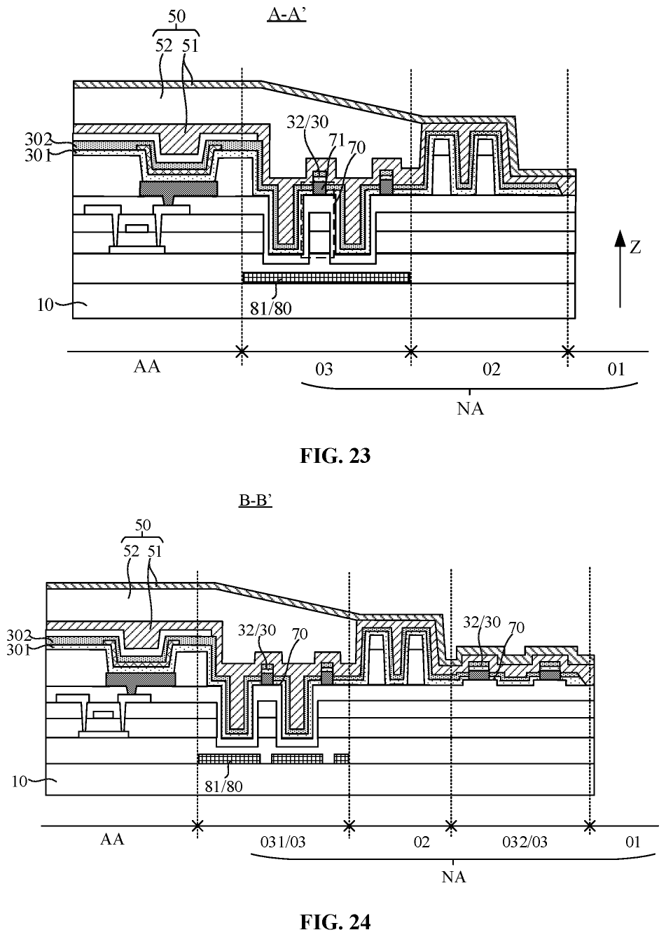

In an embodiment, FIG. 23 is another sectional diagram taken along the A-A′ line of FIG. 2. As shown in FIG. 23, along the thickness direction Z of the display panel, the second light-shielding structure 80 covers the barrier structure 70 and the gap between the barrier structure 70 and an adjacent barrier structure 70.

The second light-shielding structure 80 may be a whole-layer light-shielding structure or may also be formed by overlapping multiple light-shielding films. FIG. 23 is merely an exemplary illustration, but this is not limited herein.

Specifically, the second light-shielding structure 80 simultaneously covers the barrier structure 70 and the gap between the barrier structure 70 and the adjacent barrier structure 70 so that there can always be a certain segment difference between the second light-emitting portion 32 at the location of the barrier structure 70 and the second light-emitting portion 32 at the location of the non-barrier structure, and so that the second light-emitting portion 32 can be disconnected at this location, ensuring that the light-emitting layer 30 of the display region AA cannot be eroded by water and oxygen and improving the display effect.

In an embodiment, with continued reference to FIG. 8, FIG. 24 is another sectional diagram taken along the B-B′ line of FIG. 8. In conjunction with FIGS. 8 and 24, the barrier structure disposition region 03 includes the first barrier structure disposition region 031 and the second barrier structure disposition region 032. The first barrier structure disposition region 031 is located between the bank disposition region 02 and the display region AA, and the second barrier structure disposition region 032 is located between the bank disposition region 02 and the element disposition region 01. At least the first barrier structure disposition region 031 is provided with a second light-shielding structure 80.

Referring to FIG. 24, a barrier structure 70 is disposed in the first barrier structure disposition region 031 and the second barrier structure disposition region 032 so that the second light-emitting portion 32 located in the first barrier structure disposition region 031 and the second barrier structure disposition region 032 can be effectively disconnected from the light-emitting layer 30 in the display region AA, ensuring that the light-emitting layer 30 in the display region AA cannot be eroded by water and oxygen and thereby improving the display quality.

The number of barrier structures 70 in the first barrier structure disposition region 031 and the second barrier structure disposition region 032 may be disposed according to actual needs. This is not specifically limited herein. In addition, specific formation film structures of the barrier structures 70 in the first barrier structure disposition region 031 and the second barrier structure disposition region 032 may be the same or different. This is not specifically limited herein.

Further, since the first barrier structure disposition region 031 is much closer to the display region AA, at least the first barrier structure disposition region 031 is provided with the second light-shielding structure 80 so that the second light-shielding structure 80 can overlap the second light-emitting portion 32 located in the first barrier structure disposition region 031, and so that when the rigid substrate is lifted off by the laser, light-shielding can be at least performed on the second light-emitting portion 32 located in the first barrier structure disposition region 031, the films of the display panel can be prevented from being lifted off due to vaporization of the second light-emitting portion 32 caused by irradiating the second light-emitting portion 32 by the laser, vaporization of a common organic light-emitting layer can be prevented, the lift-off phenomenon can be prevented from extending to the display region AA, the normal performances of the common organic light-emitting layer located in the display region AA can be prevented from being affected, and the normal structure and function of the light-emitting layer 30 in the display region AA can be ensued on the premise that the structural stability of the display panel can be improved, thereby ensuring that the display region AA can normally display.

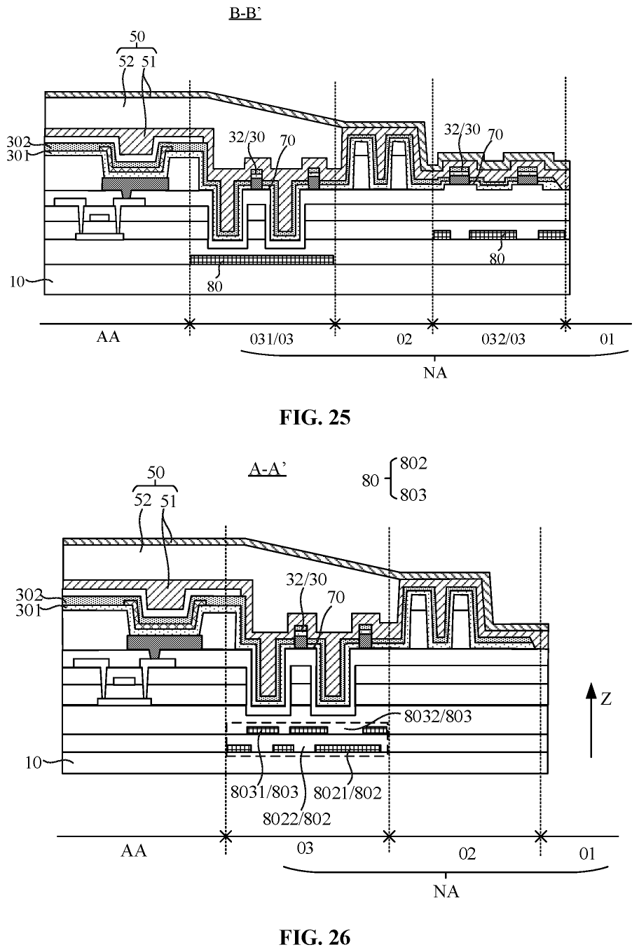

In an embodiment, FIG. 25 is another sectional diagram taken along the B-B′ line of FIG. 8. As shown in FIG. 25, the second barrier structure disposition region 032 is provided with the second light-shielding structure 80.

Specifically, the second light-shielding structure 80 disposed in the second barrier structure disposition region 032 may be a whole-layer structure or multiple independent structures. This may be disposed according to actual needs. Exemplarily, the barrier structure 70 located in the second barrier structure disposition region 032 includes the metal barrier structure, and along the thickness direction Z of the display panel, the second light-shielding structure 80 overlaps the region other than the non-metal barrier structure to perform light-shielding for the second light-emitting portion 32. In this way, the second light-shielding structure 80 is disposed in the first barrier structure disposition region 031 and the second barrier structure disposition region 032 so that the light-shielding effect of the second light-shielding structure 80 on the second light-emitting portion 32 can be increased, further preventing the second light-emitting portion 32 from being vaporized and improving the structural stability of the display panel.

It is to be noted that the second light-shielding structure 80 in the first barrier structure disposition region 031 and the second light-shielding structure 80 in the second barrier structure disposition region 032 may have the same shape or different shapes, which is not specifically limited herein. In addition, the second light-shielding structure 80 in the first barrier structure disposition region 031 and the second light-shielding structure 80 in the second barrier structure disposition region 032 may be located in the same layer or different layers, which is also not specifically limited herein. FIG. 25 is merely an exemplary illustration, and this is not limited herein and may be disposed according to actual needs.

In an embodiment, with continued reference to FIG. 25, the area of the first barrier structure disposition region 031 is S1, the coverage area of the second light-shielding structure 80 disposed in the first barrier structure disposition region 031 is S2, the area of the second barrier structure disposition region is S3, and the coverage area of the second light-shielding structure disposed in the second barrier structure disposition region 032 is S4, where (S2/S1)>(S4/S3).

Specifically, the area of the first barrier structure disposition region 031 is S1, and the coverage area of the second light-shielding structure 80 disposed in the first barrier structure disposition region 031 is S2, so the ratio of the coverage area of the second light-shielding structure 80 accounting for the area of the first barrier structure disposition region 031 is S2/S1. The larger the value of S2/S1, the better the light-shielding effect of the second light-shielding structure 80 on the first barrier structure disposition region 031. Similarly, the area of the second barrier structure disposition region is S3, and the coverage area of the second light-shielding structure 80 disposed in the second barrier structure disposition region 032 is S4, so the ratio of the coverage area of the second light-shielding structure 80 accounting for the area of the second barrier structure disposition region 032 is S4/S3. The larger the value of S4/S3, the better the light-shielding effect of the second light-shielding structure 80 on the second barrier structure disposition region 032. Further, since the first barrier structure disposition region 031 is much closer to the display region AA, and (S2/S1)>(S4/S3) is disposed, that is, the ratio S2/S1 of the coverage area of the second light-shielding structure 80 accounting for the area of the first barrier structure disposition region 031 is greater than the ratio S4/S3 of the coverage area of the second light-shielding structure 80 accounting for the area of the second barrier structure disposition region 032, the risk of the films being lifted off due to vaporization of the light-emitting layer 30 close to the display region AA can be reduced, improving the structural stability of the display panel, especially ensuring the structural stability of the display region AA.

Based on any one of the preceding embodiments, FIG. 26 is another sectional diagram taken along the A-A′ line of FIG. 2. In conjunction with FIGS. 2 and 26, the first light-shielding structure 40 includes the third light-shielding layer 402 and the fourth light-shielding layer 403 that are stacked, the third light-shielding layer 402 includes the multiple first light-shielding patterns 4021, and the fourth light-shielding layer 403 includes the multiple second light-shielding patterns 4031. The orthographic projections of the multiple first light-shielding patterns 4021 on the plane on which the substrate 10 is located and the orthographic projections of the multiple second light-shielding patterns 4031 on the plane on which the substrate 10 is located are staggered, and the orthographic projection of the third light-shielding layer 402 on the plane on which the substrate 10 is located and the orthographic projection of the fourth light-shielding layer 403 on the plane on which the substrate 10 is located cover the orthographic projection of the first light-emitting portion 31 on the plane on which the substrate 10 is located.

The second barrier structure 80 includes a fifth light-shielding layer 802 and a sixth light-shielding layer 803 that are stacked. The fifth light-shielding layer 802 includes multiple third light-shielding patterns 8021. The sixth light-shielding layer 803 includes multiple fourth light-shielding patterns 8031. Orthographic projections of the multiple third light-shielding patterns 8021 on the plane on which the substrate 10 is located and orthographic projections of the multiple fourth light-shielding patterns 8031 on the plane on which the substrate 10 is located are staggered, and the orthographic projection of the fifth light-shielding layer 802 on the plane on which the substrate 10 is located and the orthographic projection of the sixth light-shielding layer 803 on the plane on which the substrate 10 is located cover the orthographic projection of the second light-emitting portion 32 on the plane on which the substrate 10 is located

The fifth light-shielding layer 802 and the sixth light-shielding layer 803 may be stacked structures adjacent to each other or stacked structures not adjacent to each other, that is, metal layers and/or insulating layers are spaced apart and disposed between the fifth light-shielding layer 802 and the sixth light-shielding layer 803. This is not specifically limited in this embodiment of the present invention and may be disposed according to actual needs. FIG. 26 is merely an exemplary illustration, but this is not limited herein.

Specifically, the fifth light-shielding layer 802 includes the multiple third light-shielding patterns 8021 and third gaps 8022 located between adjacent third light-shielding patterns 8021, and the sixth light-shielding layer 803 includes the multiple fourth light-shielding patterns 8031 and fourth gaps 8032 located between adjacent fourth light-shielding patterns 8031. The orthographic projections of the multiple third light-shielding patterns 8021 on the plane on which the substrate 10 is located overlap orthographic projections of the fourth gaps 8032 on the plane on which the substrate 10 is located, and the area of the orthographic projection of a third light-shielding pattern 8021 on the plane on which the substrate 10 is located is greater than the area of the orthographic projection of a fourth gap 8032 on the plane on which the substrate 10 is located; and the orthographic projections of the multiple fourth light-shielding patterns 8031 on the plane on which the substrate 10 is located overlap orthographic projections of the third gaps 8022 on the plane on which the substrate 10 is located, and the area of the orthographic projection of a fourth light-shielding pattern 8031 on the plane on which the substrate 10 is located is greater than the area of the orthographic projection of a third gap 8022 on the plane on which the substrate 10 is located. In this way, the orthographic projection of the fifth light-shielding layer 802 on the plane on which the substrate 10 is located and the orthographic projection of the sixth light-shielding layer 803 on the plane on which the substrate 10 is located can completely cover the orthographic projection of the second light-emitting portion 32 on the plane on which the substrate 10 is located to ensure that the second light-shielding structure 80 can completely perform light-shielding for the second light-emitting portion 32 and prevent the films of the display panel from being lifted off due to vaporization of the second light-emitting portion caused by irradiating the second light-emitting portion 32 by the laser so that the structural stability of the display panel can be improved.

It is to be noted that based on any one of the preceding embodiments, the bank disposition region of the display panel may further be provided with the first light-shielding structure to further improve the light-shielding effect, and the first light-shielding structure and the second light-shielding structure may be located in different films or in the same film. This may be disposed according to actual needs.

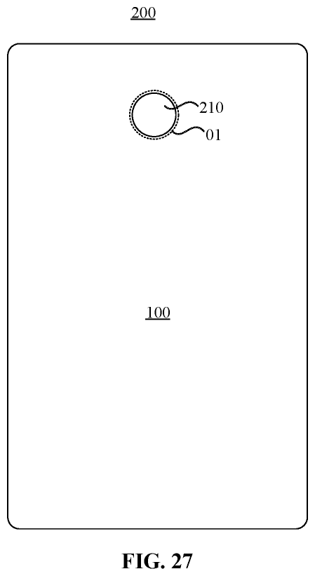

In addition, an embodiment of the present invention further provides a display device. FIG. 27 is a diagram illustrating the structure of a display device according to an embodiment of the present invention. As shown in FIG. 27, the display device 200 includes the display panel 100 according to any one of the embodiments of the present invention. The display device 200 according to this embodiment of the present invention may be a mobile phone or any electronic product having a display function, including, but not limited to, the following categories such as a television, a laptop, a desktop display, a tablet computer, a digital camera, a smart bracelet, smart glasses, an in-vehicle display, medical equipment, industrial control equipment and a touch interactive terminal. This is not specially limited in this embodiment of the present invention.

In an embodiment, the display device 200 includes a photosensitive element 210, and the photosensitive element 210 overlaps the element disposition region 01 of the display panel 100 along the thickness direction of the display panel.

The photosensitive element 210 may be a camera or an optical fingerprint recognition structure. This is not specifically limited herein and may be disposed according to actual needs.

It is to be noted that the preceding are only preferred embodiments of the present invention and technical principles used therein. It is to be understood by those skilled in the art that the present invention is not limited to the embodiments described herein. Those skilled in the art can make various apparent modifications, adaptations, combinations and substitutions without departing from the scope of the present invention. Therefore, while the present invention has been described in detail through the preceding embodiments, the present invention is not limited to the preceding embodiments and may include more other equivalent embodiments without departing from the concept of the present invention. The scope of the present invention is determined by the scope of the appended claims.

What is claimed is:

1. A display panel, comprising a display region and a non-display region, wherein the display region surrounds at least part of the non-display region;
the non-display region comprises an element disposition region and a bank disposition region surrounding at least part of the element disposition region, and the bank disposition region is provided with a bank; and
the display panel further comprises:
a substrate, wherein the bank is disposed on a side of the substrate;
a light-emitting layer located on a side of the bank facing away from the substrate and comprising a first light-emitting portion located in the bank disposition region; and
a first light-shielding structure located in the bank disposition region and on a side of the first light-emitting portion facing the substrate, wherein the first light-emitting portion and the first light-shielding structure at least partially overlap along a thickness direction of the display panel.

2. The display panel according to claim 1, wherein the non-display region further comprises a barrier structure disposition region provided with a barrier structure, the light-emitting layer is located on a side of the barrier structure facing away from the substrate and comprises a second light-emitting portion located in the barrier structure disposition region, and at least part of the second light-emitting portion is disconnected at the barrier structure; and
the display panel further comprises a second light-shielding structure located in the barrier structure disposition region and on a side of the second light-emitting portion facing the substrate, and the second light-emitting portion and the second light-shielding structure at least partially overlap along the thickness direction of the display panel.

3. The display panel according to claim 2, wherein the barrier structure comprises metal barrier structures; and
the second light-shielding structure comprises a plurality of independent second light-shielding portions, and along the thickness direction of the display panel, a second light-shielding portion of the plurality of second light-shielding portions overlaps a gap between two adjacent metal barrier structures of the metal barrier structures.

4. The display panel according to claim 3, wherein a thickness of the second light-emitting portion is less than a thickness of the barrier structure along the thickness direction of the display panel.

5. The display panel according to claim 2, wherein the second light-shielding structure covers the barrier structure and a gap between the barrier structure and an adjacent barrier structure along the thickness direction of the display panel.

6. The display panel according to claim 2, wherein the barrier structure disposition region comprises a first barrier structure disposition region and a second barrier structure disposition region, the first barrier structure disposition region is located between the bank disposition region and the display region, and the second barrier structure disposition region is located between the bank disposition region and the element disposition region; and
at least the first barrier structure disposition region is provided with the second light-shielding structure,
wherein the second barrier structure disposition region is provided with the second light-shielding structure.

7. The display panel according to claim 6, wherein an area of the first barrier structure disposition region is S1, a coverage area of the second light-shielding structure disposed in the first barrier structure disposition region is S2, an area of the second barrier structure disposition region is S3, and a coverage area of the second light-shielding structure disposed in the second barrier structure disposition region is S4,
wherein (S2/S1)>(S4/S3).

8. The display panel according to claim 2, wherein the display region further comprises a plurality of sub-pixels;
the display plane further comprises a signal wire electrically connected to the plurality of sub-pixels and comprising a wire portion surrounding part of the element disposition region; and
the wire portion satisfies at least one of: the wire portion serves as the first light-shielding structure, or the wire portion serves as the second light-shielding structure.

9. The display panel according to claim 8, wherein the signal wire comprises a gating signal line and an initialization signal line; and the gating signal line or the initialization signal line serves as the first light-shielding structure, or
wherein the signal wire comprises a gating signal line, a data signal line, an initialization signal line and a power signal line;
the gating signal line, the data signal line, the initialization signal line and the power signal line all serve as the second light-shielding structure; and
along the thickness direction of the display panel, the gating signal line or the initialization signal line overlaps a gap between two adjacent barrier structures, and the data signal line or the power signal line overlaps the barrier structure.

10. The display panel according to claim 2, wherein an area of the bank disposition region is S5, a coverage area of the first light-shielding structure is S6, an area of the barrier structure disposition region is S7, and a sum of a coverage area of the barrier structure and a coverage area of the second light-shielding structure is S8,
wherein |(S6/S5)−(S8/S7)|/{[(S6/S5)+(S8/S7)]/2}≤20%.

11. The display panel according to claim 2, wherein the first light-shielding structure comprises a first overall light-shielding structure, and the second light-shielding structure comprises a second overall light-shielding structure.

12. The display panel according to claim 2, wherein the first light-shielding structure comprises at least one first light-shielding layer, and the second light-shielding structure comprises at least one second light-shielding layer; and
the at least one first light-shielding layer and the at least one second light-shielding layer are in a same layer.

13. The display panel according to claim 1, wherein the display region comprises a plurality of sub-pixels, and a sub-pixel of the plurality of sub-pixels comprises a light-emitting element and a pixel circuit that are interconnected;
the light-emitting element comprises an anode, the pixel circuit comprises a transistor, and the transistor comprises an active layer, a gate and a source/drain electrode;
the display panel further comprises a shield protection structure located between a film in which the substrate is located and a film in which the pixel circuit is located; and
the first light-shielding structure is in a same layer as at least one of the anode, the active layer, the gate, the source/drain electrode, or the shield protection structure,
wherein the first light-shielding structure is at least in a same layer as a structure having a minimum film thickness among the anode, the active layer, the gate, the source/drain electrode and the shield protection structure.

14. The display panel according to claim 1, wherein the first light-shielding structure comprises a third light-shielding layer and a fourth light-shielding layer that are stacked, the third light-shielding layer comprises a plurality of first light-shielding patterns, and the fourth light-shielding layer comprises a plurality of second light-shielding patterns; and
orthographic projections of the plurality of first light-shielding patterns on a plane on which the substrate is located and orthographic projections of the plurality of second light-shielding patterns on the plane on which the substrate is located are staggered, and an orthographic projection of the third light-shielding layer on the plane on which the substrate is located and an orthographic projection of the fourth light-shielding layer on the plane on which the substrate is located cover an orthographic projection of the first light-emitting portion on the plane on which the substrate is located.

15. The display panel according to claim 1, wherein the bank comprises light-nontransmissive banks; and
the first light-shielding structure overlaps a gap between two adjacent light-nontransmissive banks of the light-nontransmissive banks along the thickness direction of the display panel.

16. The display panel according to claim 1, wherein the first light-shielding structure is electrically connected to a fixed potential terminal.

17. The display panel according to claim 1, further comprising an encapsulation structure located on a side of the light-emitting layer facing away from the substrate,
wherein the encapsulation structure comprises an organic encapsulation layer located between two inorganic encapsulation layers, and the organic encapsulation layer ends at a location of the bank.

18. A display panel, comprising a display region and a non-display region, wherein the display region surrounds at least part of the non-display region;
the non-display region comprises an element disposition region and a barrier structure disposition region surrounding at least part of the element disposition region, and the barrier structure disposition region is provided with a barrier structure; and
the display panel further comprises:
a substrate, wherein the barrier structure is disposed on a side of the substrate;
a light-emitting layer located on a side of the barrier structure facing away from the substrate and comprising a second light-emitting portion located in the barrier structure disposition region, wherein at least part of the second light-emitting portion is disconnected at the barrier structure; and
a second light-shielding structure located in the barrier structure disposition region and on a side of the second light-emitting portion facing the substrate, wherein the second light-emitting portion and the second light-shielding structure at least partially overlap along a thickness direction of the display panel.

19. A display device, comprising a display panel
wherein the display panel comprises a display region and a non-display region, wherein the display region surrounds at least part of the non-display region;
the non-display region comprises an element disposition region and a bank disposition region surrounding at least part of the element disposition region, and the bank disposition region is provided with a bank; and
the display panel further comprises:
a substrate, wherein the bank is disposed on a side of the substrate;
a light-emitting layer located on a side of the bank facing away from the substrate and comprising a first light-emitting portion located in the bank disposition region; and
a first light-shielding structure located in the bank disposition region and on a side of the first light-emitting portion facing the substrate, wherein the first light-emitting portion and the first light-shielding structure at least partially overlap along a thickness direction of the display panel.

20. The display device according to claim 19, comprising a photosensitive element, wherein the photosensitive element overlaps the element disposition region of the display panel along a thickness direction of the display panel.
